(19) United States
(12) Patent Application Publication
(10) Pub. No.: US 2013/0206219 A1
(43) Pub. Date: Aug. 15, 2013

(54) COOPERATIVE PHOTOVOLTAIC NETWORKS AND PHOTOVOLTAIC CELL ADAPTATIONS FOR USE THEREIN

(71) Applicants: Juanita N. Kurtin, Hillsboro, OR (US); Alex R. Guichard, Durham, NC (US); Alex C. Mayer, Portland, OR (US); Shawn R. Scully, San Francisco, CA (US); Steven M. Hughes, Walla Walla, WA (US); Oun-Ho Park, San Jose, CA (US); Paul-Emile B. Trudeau, Ottawa (CA); Colin C. Reese, Portland, OR (US); Manav Sheoran, Beverly, MA (US); Georgeta Masson, Lafayette, CA (US)

(72) Inventors: Juanita N. Kurtin, Hillsboro, OR (US); Alex R. Guichard, Durham, NC (US); Alex C. Mayer, Portland, OR (US); Shawn R. Scully, San Francisco, CA (US); Steven M. Hughes, Walla Walla, WA (US); Oun-Ho Park, San Jose, CA (US); Paul-Emile B. Trudeau, Ottawa (CA); Colin C. Reese, Portland, OR (US); Manav Sheoran, Beverly, MA (US); Georgeta Masson, Lafayette, CA (US)

(21) Appl. No.: 13/814,210

(22) PCT Filed: Jul. 27, 2011
(86) PCT No.: PCT/US11/45466

§ 371 Date: Apr. 11, 2013

(30) Foreign Application Priority Data
Aug. 6, 2010 (US) 61371594
Aug. 6, 2010 (US) 61371603
Dec. 2, 2010 (US) 61419182

(51) Int. Cl. H01L 31/06

(52) U.S. Cl. CPC H01L 31/06
USPC 136/255

(57) ABSTRACT

Photovoltaic cells (22) of different materials may be integrated at the network (20) or panel level to optimize independent and cooperative efficiencies and manufacturing techniques of the different materials. The sizes and numbers of the photovoltaic cells (22) in the separate photovoltaic networks (20) may differ. Separate fabrication of the different photovoltaic networks (20) permits optimization of an interlayer material (110), which can be insulating or noninsulating and can include one or more of light-scattering or light-emitting particles, photonic crystals, metallic materials, an optical grating, or a refractive index grading. For example, adaptations of increased emitter layer thickness, lower sheet resistance, increased gridline spacing, smoother photovoltaic material surface, and/or increased AR coating thickness are made to a multicrystalline silicon photovoltaic cell (20) for optimization as a bottom network (20b) of a tandem solar module. In some embodiments, a photovoltaic device includes two component cells, (22a, 22c) having substantially similar primary bandgap energies (or absorption spectra), and at least a third component cell (22b) having a different primary bandgap energy.

### RELATED APPLICATION

This application claims the benefit under 35 U.S.C. §119(e) of International Application Number PCT/US11/45466 filed Jul. 27, 2011, U.S. Provisional Patent Application No. 61/419,182, filed Dec. 12, 2010, U.S. Provisional Patent Application No. 61/371,594, filed Aug. 6, 2010, and U.S. Provisional Patent Application No. 61/371,603, filed Aug. 6, 2010, and this application is a continuation-in-part of U.S. patent application Ser. No. 12/836,511, filed Jul. 14, 2010, which claims the benefit under 35 U.S.C. §119(e) of U.S. Provisional Patent Application No. 61/225,472, filed Jul. 14, 2009.

### COPYRIGHT NOTICE

©2011 Spectrawatt, Inc. A portion of the disclosure of this patent document contains material that is subject to copyright protection. The copyright owner has no objection to the facsimile reproduction by anyone of the patent document or the patent disclosure, as it appears in the Patent and Trademark Office patent the or records, but otherwise reserves all copyright rights Whatsoever. 37 CFR §1.71(d).

### TECHNICAL FIELD

This invention relates to tandem photovoltaic networks and, in particular, to a network or photovoltaic cell adaptation for use as a top, middle, or bottom component in a tandem photovoltaic network.

### BACKGROUND

FIG. 1 is a graph showing the distribution of photons of sunlight reaching the earth's surface as a function of their energy. The graph also shows that sunlight is composed of a broad distribution of energies (or wavelengths).

Materials, particularly semiconducting materials used in optoelectronics, have an energy (e.g., eV) or wavelength (e.g., nm) associated with their light absorption properties called a bandgap (E_{g}). When photons of sunlight shine upon these materials, photons with energies at and above the bandgap will be absorbed by the material and will create excited charge carriers, and the material will be transparent to photons with energies below the bandgap. The excited charge carriers are collected by electrodes in proximity to a charge-separating junction to express an electric current.

Unfortunately, the conventional materials used in photovoltaic devices have efficiencies far below the theoretical maximum. The maximum thermodynamic power conversion efficiency that a photovoltaic device can attain under the standard non-concentrated solar spectrum is up to about 70%. Despite this nigh potential, the world record efficiency for a single-junction solar device remains below 30%, and typical solar cells coming off high-volume production lines have efficiencies below (sometimes far below) 20%. For example, state-of-the-art high-volume manufacturing fines of multicrystalline silicon typically yield solar cells with efficiencies of less than or equal to 16%.

These standard multicrystalline silicon (mc-Si) solar cells are composed of a p-type mc-Si wafer with a diffused phosphorus emitter, a silicon nitride front passivation/antireflective (AR) coating, a screen-printed blanket aluminum back contact and a screen printed, fire-through nitride front silver grid contact.

The standard mc-Si solar cells are designed to maximize the spectral response of the mc-Si solar cells across a broad range of wavelengths in the solar spectrum (roughly 300-1150 nm) in order to capture as much of the incident light as possible. This design strategy causes a number of trade-offs particularly with respect to a multi-parameter optimization of photogenerated current and voltage and of series and shunt resistances.

Many losses limit the efficiency to something far below the theoretical maximum. When a photon of energy larder than the bandgap of the semiconductor is absorbed by the semiconductor, the excess energy, initially stored in the excited carrier, is quickly lost to heat when the photo-excited carrier decays to the band edge. This process is called thermalization and limits the maximum thermodynamic efficiency for single (junction) photoactive material devices to less than 30%.

Silicon, for example, has a bandgap of less than about 1.1 eV. With reference to FIG. 1, many photons with energy much higher than 1.1 eV will impinge slit photovoltaic material. A 2 eV photon will, for example, be absorbed by the silicon and then lose at least 2 eV−1.1 eV=0.9 eV to thermalization.

There are multiple ways to prevent this loss from occurring. One approach involves monolithic stacking of multiple materials each with a unique bandgap to form a multijunction solar cell. Such solar cells are optically engineered to encourage higher energy photons to be absorbed by higher bandgap materials and lower energy photons to be absorbed by the lower bandgap materials. The materials are typically arranged from highest bandgap to lowest bandgap such that the top or front photovoltaic; material absorbs (and consequently filters off) the highest energy photons, and each successively lower material absorbs and filters off the next lowest energy range of photons.

Several types of two-junction solar cells have been developed. For example, amorphous Si/multicrystalline Si (a-Si/mc-Si) two-junction tandem solar cells have been developed in which the two component cells can be wired either in series or with four separate electrical terminals instead of two. See Matsumoto, Y. et al., “a-Si/poly-Si two- and four-terminal tandem type solar cells.”, Conference Record of the 21st IEEE PVSC, 21-25 May 1990, page 1420. Another example is a-Si/μc-Si “micromorph” solar cells that are being sold on the market as a lower-efficiency thin-film alternative to crystalline Si (c-Si) solar cells.

The materials are also usually chosen to closely match the optimal bandgap values the theoretical maximum achievable efficiency for a given number component cells. For instance, in a three junction solar cell, the optimal efficiency is achieved with three component cells with bandgaps of 2.3, 1.4, and 0.8 eV under one sun illumination. This combination achieves the best splitting of the solar spectrum for an overall higher efficiency.

Thermalization is decreased because high-energy photons only thermalize to the band edge of the high bandgap material, mid-energy photons to the band edge of the mid bandgap materials, and low-energy photons to the band edge of the low bandgap materials. This design increases the theoretical efficiency from less than 30% for a single-junction cell to 42% for a two-junction epitaxial solar cell, and to 49% for a three-junction epitaxial solar cell in which each junction collects excited camera absorbed by materials with different bandgaps. Each additional junction increases the maximum achievable conversion efficiency by reducing losses to thermalization.

This architecture has been successful with efficiencies of 41% under concentrated sunlight and 31% under one-sun conditions achieved with a three-junction monolithic epitaxial solar cell using GaInP₂, GaAs, and Ge as the photovoltaic materials that form the junctions. Even though these relatively high efficiencies have been achieved, these monolithic multijunction cells are epitaxially drown using Metal-Organic Chemical Vapor Deposition (MOCVD) in a batch wafer process, which is an extremely slow manufacturing process. Epitaxial growth also requires lattice matching to prevent interfacial defects. The list of additional high cost-limiting constraints for this technology is extensive. The substrate for these triple-junction solar cells Ge wafer material, which costs about $25,000/m² and is extremely expensive compared to less than $200/m² for solar-grade silicon wafer material made in a high throughput inline process.

It is therefore desirable to improve the efficiency of solar devices and reduce their cost of fabrication.

### SUMMARY

One aspect of the invention is, therefore, to provide a first network of first photovoltaic cells having a first photovoltaic material for connection to a second network of second photovoltaic cells having a second photovoltaic material, wherein the first and second photovoltaic materials have different bandgaps.

In one embodiment, the first photovoltaic cells have first surface area dimensions that are different from second surface area dimensions of the second photovoltaic cells.

In a separate or additive embodiment, the first network has a different number of first photovoltaic cells than the second network has of the second photovoltaic cells.

In a separate or additive embodiment; the first network having a first number of first photovoltaic cells is electrically connected in series to the second network having a different second number of the second photovoltaic cells.

In a separate or additive embodiment, the first network produces a first current density that matches a second current density produced by the second network to within 1%.

In as separate or additive embodiment, the first and second photovoltaic materials have respective first and second bandgaps that are nonoverlapping.

In a separate or additive embodiment, the first and second photovoltaic materials are respectively manufactured under incompatible process conditions.

In a separate or additive embodiment, an interlayer between the first network of first photovoltaic cells and the second network of second photovoltaic cells has a thickness greater than a wavelength corresponding to the lowest of the lower ends of the respective bandgaps of the first and second photovoltaic materials.

In a separate or additive embodiment, an interlayer between the first network of first photovoltaic cells and the second network of second photovoltaic cells has a thickness greater than 1000 nm.

In a separate or additive embodiment, an interlayer between the first network of first photovoltaic cells and the second network of second photovoltaic cells includes an optical structure.

In a separate or additive embodiment, the optical structure includes at least one of a layer of light-scattering or light-emitting particles embedded in a matrix, an optical grating, and photonic crystals.

In a separate or additive embodiment, an interlayer between the first network of first photovoltaic cells and the second network of second photovoltaic cells includes a graded refractive index.

In a separate or additive embodiment, an interlayer between the first network of first photovoltaic cells and the second network of second photovoltaic cells includes an insulator layer.

In a separate or additive embodiment, an interlayer between the first network of first photovoltaic cells and the second network of second photovoltaic cells includes a metallic material.

In a separate or additive embodiment, a bottom network employs an mc-Si-based photovoltaic tell that is adapted for use as a low handclap absorber.

In some separate or additive embodiments, a multijunction photovoltaic device includes two component cells with similar primary bandgap energies.

In some separate or additive embodiments, the two component cells have photovoltaic materials with primary bandgap energies that differ by less than 20%.

In some separate or additive embodiments, the two component cells have photovoltaic materials with primary bandgap energies that that differ by less than 10%.

In some separate or additive embodiments, the two component cells have photovoltaic materials with primary bandgap energies that differ by less than 170 meV.

In some separate or additive embodiments, at least one of the photovoltaic materials has a primary, bandgap energy within a range of 1.6-2.0 eV.

In some separate or additive embodiments, the two component cells employ a common photovoltaic material.

In some separate or additive embodiments, a tunnel junction is positioned between the photovoltaic materials of the two component cells.

In some separate or additive embodiments, at least one of the two component cells employs a thin transparent conductive oxide electrode.

In some separate or additive embodiments, the two component cells have a different thickness.

In some separate of additive embodiments, an additional component cell includes a photovoltaic material that is different from the photovoltaic materials of the two component cells.

In some separate or additive embodiments, the additional component cell has a bandgap energy that is substantially different from the bandgap energies of the two component cells.

The additive embodiments can be combined except in the cases where they are mutually exclusive.

Additional aspects and advantages will be apparent from the following detailed description of preferred embodiments, which proceeds with reference to the accompanying drawings.

### BRIEF DESCRIPTION OF THE DRAWING

FIG. 1 is a graph snowing the distribution of photons of sunlight reaching the earth's surface as a function of their energy.

FIG. 2 is a series of isometric views that present an overview of a simplified process that stacks at least two photovoltaic networks or modules to form a hybrid solar panel.

FIGS. 3A and 3B are respective isometric and cross-sectional views of multiple wafer-based photovoltaic cells electrically connected to form a wafer-based photovoltaic network or module.

FIG. 4 is a series of sectional views showing simplified process steps for fabricating a thin-film network.

FIG. 4A is a schematic diagram of an exemplary two-network photovoltaic module.

FIG. 5A is an isometric view of a multijunction photovoltaic stack wherein the high bandgap photovoltaic cell and the underlying low bandgap photovoltaic cell are electrically connected in series.

FIG. 5B is a circuit diagram representing the electronic series configuration of the photovoltaic cells of FIG. 5A.

FIG. 6 is a graph of the maximum current density a photovoltaic cell can generate as a function of its bandgap under AM1.5G sunlight.

FIG. 7A is an isometric view of hybrid solar panel components haying different photovoltaic cells of different networks interconnected in an exemplary cooperative hybrid electronic configuration.

FIG. 7B is an isometric view of an enlarged portion of FIG. 7A, showing the electronic interconnections of the different photovoltaic cells in the different networks.

FIG. 8 is a cross-sectional view of a simplified hybrid solar panel showing transmission of light through the cell interconnects of a high bandgap network to, a low bandgap network.

FIG. 9 is a cross-sectional view of a hybrid solar panel showing exemplary interconnection between the high handclap network and the low bandgap network.

FIG. 10 is an isometric view of a portion of a triple-junction photovoltaic panel with sections cut away to show the different networks and intervening layers.

FIG. 11 is an isometric view of a portion of a triple-junction photovoltaic panel with the different networks spaced apart to show network interconnections.

FIG. 12 is an enlarged sectional side view of a portion of two-junction photovoltaic panel showing selective light reflection by a optical interlayer.

FIGS. 13A, 13B, 13C, and 13D are respective plan, plan, perspective, and sectional views of respective one-dimensional, two-dimensional, three-dimensional, and three-dimensional exemplary refractive index embodiments of an optical interlayer.

FIG. 14 is simplified enlarged drawing of an encapsulated quantum dot heterostructure.

FIGS. 15A, 15B, and 15C are schematic cross-sectional views of the top surface of mc-Si cells, respectively showing the emitter thickness and sheet resistance of respective standard solar cells for single-junction applications, future solar cells for single-junction applications, and photovoltaic cells for use in bottom networks of tandem solar panels.

FIG. 16 is a graph showing simulated Internal Quantum Efficiency (IQE) curves as a function of wavelength for three different emitter sheet resistances.

FIG. 17 is a simplified plan view of a typical top grid contact for a bottom network Si photovoltaic cell.

FIG. 18 is a schematic cross-sectional view of a two-layer configuration on the to surface of a Si-based bottom network photovoltaic cell.

FIG. 19 is a graph showing simulated reflectance plots for different thickness combinations of SiNₓ and SiOₓ.

FIG. 20A is a graph showing the a-Si bandgap as a function of hydrogen concentration.

FIG. 20B is a graph showing the a-Si bandgap as a function of methane concentration.

FIG. 21 is a schematic diagram of an exemplary multijunction photovoltaic device having two junctions within photovoltaic, material having similar bandgap energies.

FIG. 22 is a schematic diagram of an embodiment of the multijunction photovoltaic device of FIG. 21 with a top pair of component cells electrically wired in parallel with a bottom component cell.

FIG. 23 is a schematic diagram of an embodiment of the multijunction photovoltaic device of FIG. 21 with a top pair of component cells electrically wired in series with a bottom component cell.

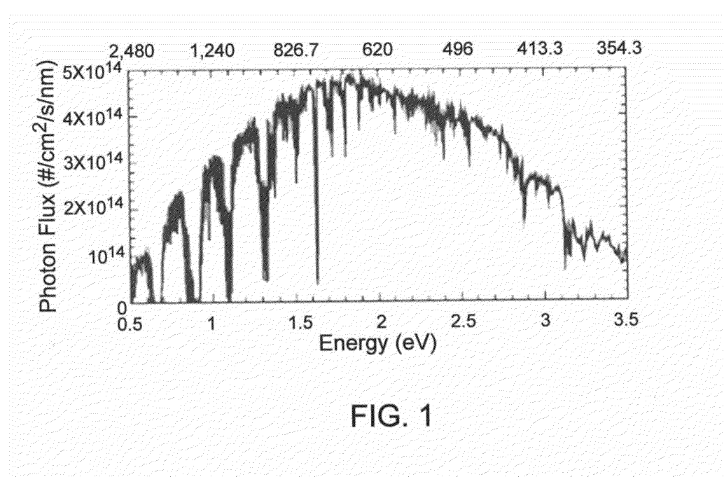

### DETAILED DESCRIPTION OF PREFERRED EMBODIMENTS

Multijunction solar cells offer numerous technological advantages over their single-junction counterparts. First, the sharing of the solar spectrum amongst multiple semiconductor materials with varying bandgap permits less photon energy to be lost to heat as electron-hole pairs relax to the band edge. This reduction in loss allows the multijunction cell to produce more voltage and thus more power than a single-junction cell. Second, using multiple junctions enables capturing of a larger portion of the solar spectrum than compared to the portion of the solar spectrum captured by a single-junction mil with optimum bandgap. According to the theorized Shockley-Queisser Limit, the optimum absorption onset for a single-junction cell is between about 885 nm and 1000 nm. However, the solar spectrum has measurable photon density out to 2500 nm, so the radiation between about 1000-2500 nm is wasted by an optimum single junction cell. So adding another junction material, with an absorption onset in that long wavelength region, beneath such cell permits part of that previously unabsorbed radiation to be convened to electrical power.

Combining multiple junctions in a solar cell is, therefore, a means to achieve higher efficiencies; however, there are many challenges that arise with a multijunction architecture. One challenge is ensuring that the proper regions of the spectrum reach the appropriate component cells.

In monolithic multijunction architectures, the approach is fairly straightforward as long as small light absorption losses are tolerable. However, monolithic multijunction cells suffer from lack of optimization of absorption opportunities by the upper and lower photovoltaic because thin top cells often do not efficiently absorb enough light in one pass and because reflections off of the interfaces between the cells can lead to loss.

Furthermore, traditional cell architecture and manufacturing techniques employed for producing monolithic and, particularly, epitaxial multijunction solar cells are prohibitively expensive for generation of cost-competitive solar electricity. Conventional multijunction epitaxial solar cells have a cell architecture in which the individual photovoltaic materials are monolithically stacked and all grown using a common, epitaxial, spatially contiguous process (e.g. an all metalorganic chemical vapor deposition (MOCVD) process or an all plasma-enhanced chemical vapor deposition (PECVD) process, etc.). The direct series electrical connection between the subcomponent photovoltaic materials of these mutt junction epitaxial solar cells limits their electrical current propagation to that produced by the feast productive of the subcomponent photovoltaic materials.

Even though such architecture can be made efficient, there are tremendous constraints that limit the flexibility in material selection, material growth, and the resultant production cost of these multijunction epitaxial solar cells. For example, one material may not be stable under processing conditions ideal for another, growth of one material may not proceed optimally on the other, and only a small window of bandgap combinations may work efficiently because the total tandem current will be limited by the subcomponent photovoltaic material with the lowest current producing capacity, as later described in greater detail.

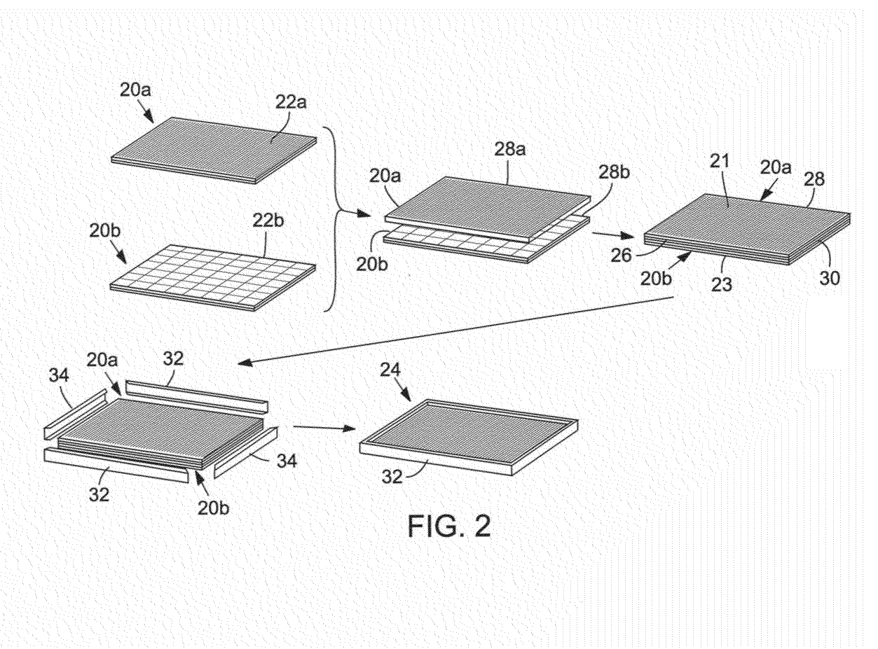

Configuring separate photovoltaic networks having different photovoltaic materials to work together can address many of these issues. FIG. 2 provides an overview of a simplified process that stacks at least two photovoltaic networks or modules 20a and 20b (generically, networks or modules 20) of respective top (also typically upper, front or sun-facing) photovoltaic cells 22a and bottom (also typically lower, back, rear, or earth-facing) photovoltaic cells 22b of respective different photovoltaic materials to form a hybrid solar panel 24. The alternative designations refer to the intended relative positioning of the photovoltaic cells 22a and 22b during operation after installation but may not be representative of the positioning during manufacture or transport. The photovoltaic networks 20s and 20b are fabricated independently. In some embodiments, one or more of the networks 20 may be monolithically integrated. Also, one or more of the networks 20 may utilize hybrid integration. In some embodiments, a hybrid-integrated network of silicon photovoltaic cells is paired with a monolithically integrated network of thin-film photovoltaic cells.

Herein only by way of example, FIG. 2 shows panel level integration for a hybrid two-network multijunction solar panel 24 including both a monolithic photovoltaic network 20a and a hybrid integrated photovoltaic network 20b. The photovoltaic networks 20a and 20b form the top (also typically upper, front, or sun facing) and bottom (also typically lower, back, or earth-facing) sides 21 and 23 of the panel 24, typically with the higher bandgap photovoltaic network 20b being at the top and the lower bandgap photovoltaic network 20b being on the bottom. The photovoltaic networks 20a and 20b are stacked on opposite sides of an interlayer 26 and electrically coupled. Edges 28 and 30 of the stacked networks 20 may be sealed and framed with frame pieces 32 and 34 to provide a durable hybrid solar panel or module 24.

The stacking of at least two networks 20a and 20b of photovoltaic cells 22a and 22b of different photovoltaic materials rather than fabricating the different photovoltaic materials into an individual solar cell can overcome many of the previously mentioned limitations. For example rather than growing the different photovoltaic materials monolithically and, particularly, epitaxially and being subject to all the dependent complications; fabrication of the charge-separation junctions of the two or more different photovoltaic materials can be decoupled such that each network 20 of the different photovoltaic cells can be manufactured with different manufacturing processes and can even be manufactured in different facilities. Combinations of the photoactive materials can be optimized to work together for efficiency, and the manufacturing processes for each network 20 of these different materials can be independently optimized for higher efficiency and high-volume, low-cost manufacturing techniques. Even manufacturing processes that are mutually exclusive in the fabrication of epitaxial multijunction solar cells can be used to make the photovoltaic; networks 20a and 20b of different photovoltaic materials. The individually manufactured photovoltaic networks 20a and 20b are then stacked to form a highly efficient solar panel 24.

The photovoltaic networks 20 and their photovoltaic materials can be optimized for different parts of the solar spectrum such that the sum of the power output is greater than the output from any individual network or photovoltaic material optimized for efficiency over the entire solar spectrum. (Any individual photovoltaic material optimized for efficiency over the entire solar spectrum will exhibit regions or absorption that will be less efficient than materials optimized for absorption in the specific region. Furthermore, optimization of a material for the entire solar spectrum may also cause absorption in its best absorption regions to be diminished to enhance absorption in other regions of the spectrum.)

In some embodiments, a photovoltaic, network 20b of lower bandgap wafer-based photovoltaic cells 22b having a photovoltaic material optimized for a first primary absorption spectrum in the near infrared (NIR) through the visible/infrared (VIS/IR) portion of the spectrum is employed with a photovoltaic network 20a of higher bandgap thin-film photovoltaic cells 22a having a different photovoltaic material optimized for a second primary absorption spectrum in the ultraviolet (UV) through the VIS/IR portion of the spectrum. The primary absorption spectra of the photovoltaic materials may overlap or be nonoverlapping. The amount of overlap may be influenced by efficiency, ease of manufacture, cost, or other factors.

The photovoltaic material used as absorber in the lower bandgap network 20b of a hybrid soar panel 24 can include, but is not limited to, one or more of: c-Si (crystalline silicon), mc-Si, thin-film Si, GaAs, GaₓIn₁₋ₓAs, GaₓIn₁₋ₓAs_{y}N_{1-y}, AlₓGa₁₋ₓAs, AlₓGa₁₋ₓAs_{y}N_{1-y}, InₓGa₁₋ₓN, InP, InPₓN₁₋ₓ, Zn₃P₂, CuInS₂, CuInSe₂, CuGaS₂, CuGaSe₂, CuInₓGa₁₋ₓS_{(y)2}Se_{(1-y)2}, CuAlSe₂, CuInAlSe₂, CuInₓGa₁₋ₓSe₂, CuZnₓSn₁₋ₓS₂, CuZnₓSn₁₋ₓSe₂. In general, the photovoltaic material of a lower bandgap network 20b has a wavelength absorption onset at a wavelength less than or equal to about 2000 nm, and such photovoltaic material typically absorbs a major portion of the wavelengths between about 2000 nm and about 300 nm. The photovoltaic materials of these networks 20b tend to transmit 0% of the light of wavelengths shorter than the absorption onset.

The photovoltaic material used as absorber in the higher bandgap network 20a of a two-junction solar module 24 can include, but is not limited to, one or more of: a-Si (amorphous silicon), a-SiC (amorphous silicon carbide), GaₓIn₁₋ₓP, InₓGa₁₋ₓN, ZnSe, CdSe, CdS, CuO, CuIn₁₋ₓGaₓSe_{2-y}S_{y}, CdZnTe, CuZnSn₁₋ₓS₂. In general, the photovoltaic material of a higher bandgap network 20a has a wavelength absorption onset at a wavelength less than or equal to about 1100 nm, and such photovoltaic material typically absorbs wavelengths between about 1100 nm and about 300 nm. The photovoltaic materials of these networks 20a tend to transmit greater than 70% of the light of wavelengths shorter than the absorption onset and tend to reflect less than 20% of the light of wavelengths shorter than the absorption onset.

In some embodiments, one, two, or all of the networks may employ photovoltaic materials that include quantum dot ensembles as disclosed in detail in U.S. patent application Ser. No. 12/606,908, entitled Solar Cell Constructed with Inorganic Quantum Dots and Structured Molecular Contacts, which is herein incorporated by reference.

Although some combinations of photovoltaic materials from the lists of materials for higher and lower bandgap networks may be more practical for cost, cooperative or total wavelength absorption ranges, or otherwise-practical or manufacturing considerations, any photovoltaic material that can be used for the network 20a can be paired with any photovoltaic material that can be used for the network 20b. In one embodiment, the network 20b includes photovoltaic cells 22b that employ a wafer-based mc-Si photovoltaic material, and the network 20a includes photovoltaic cells 22a that employ a thin-film amorphous Si (a-Si) photovoltaic material. In another embodiment, the network 20b includes photovoltaic cells 22b that employ a wafer-based mc-Si photovoltaic, material, and the network 20a includes photovoltaic cells 22a that employ a polycrystalline thin-film ZnSe or CdSe photovoltaic material. In another embodiment, the network 20b includes photovoltaic cells 22b that employ a wafer-based GaAs photovoltaic material, and the network 20a includes photovoltaic cells 22a that employ a polycrystalline thin-film ZnSe or CdSe photovoltaic material. In another embodiment, the network 20b includes photovoltaic cells 22b that employ a flexible substrate-based CuInₓGa₍₁₋ₓ₎Se₂ thin-film photovoltaic material, and the network 20a includes photovoltaic cells 22a that employ a polycrystalline thin-film ZnSe or CdSe photovoltaic, material. In another embodiment, the network 20b includes photovoltaic cells 22b that employ a flexible substrate-based CuInGa₍₁₋ₓ₎Se₂ thin-film photovoltaic material, and the network 20a includes photovoltaic cells 22a that employ a thin-film a-Si photovoltaic material.

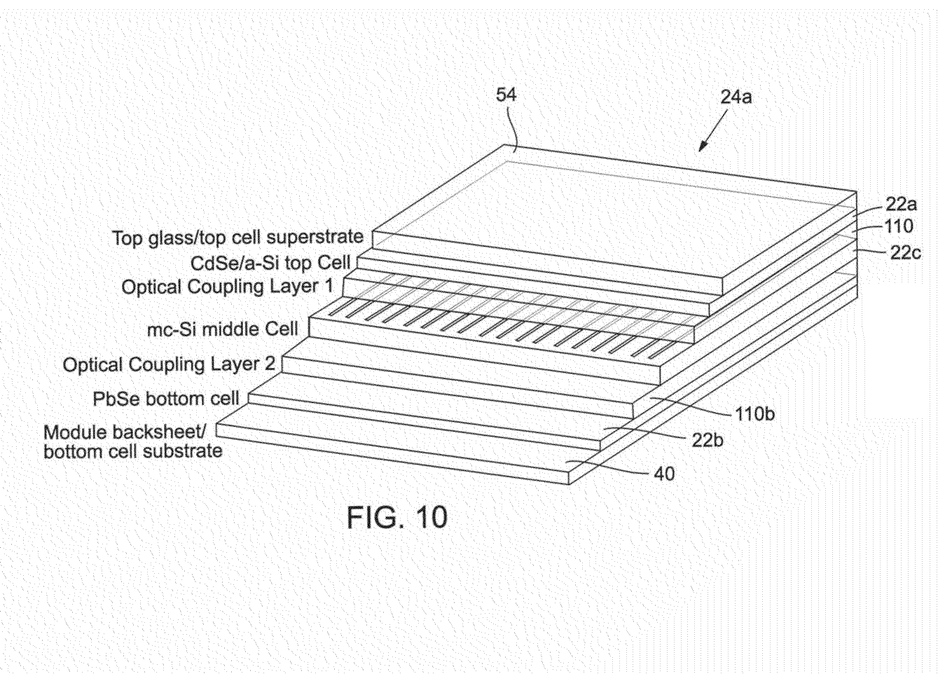

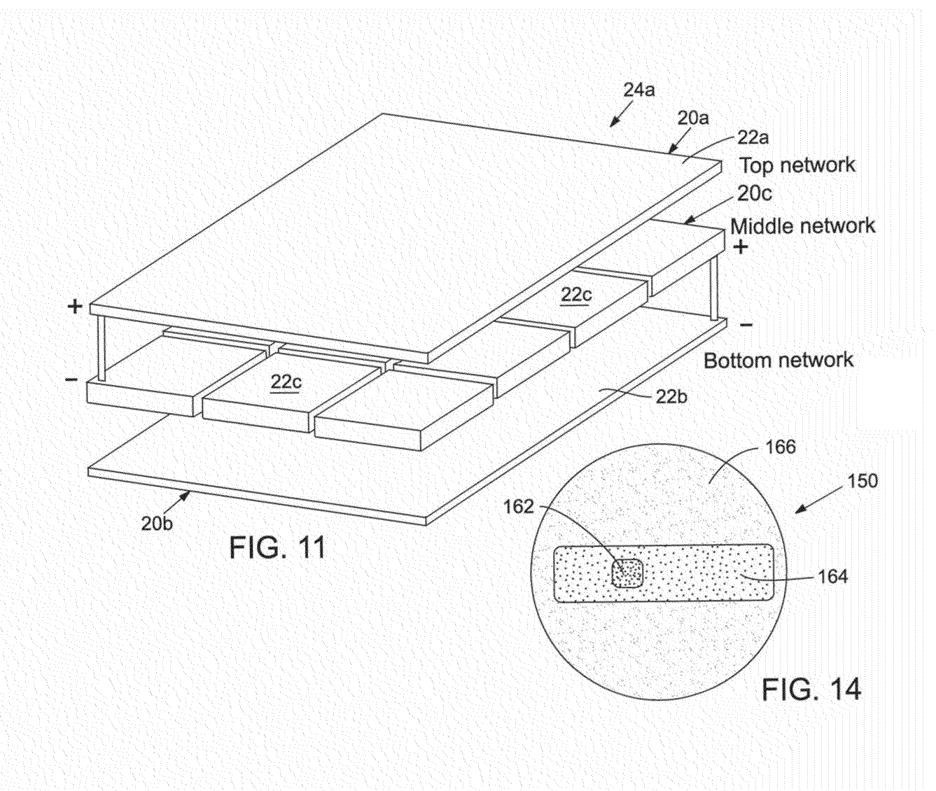

In some embodiments, the incident solar spectrum can be divided into three or more primary absorption spectra. In a three-junction network, the photovoltaic, material used as absorber in the lowest bandgap network can include, but is not limited to, one or more of Ge, PbS, PbSe, InₓGa₁₋ₓN, GaₓIn₁₋ₓAs_{y}N_{1-y}, AlₓGa₁₋ₓAs_{y}N_{1-y}, and Cu(InₓGa₁₋ₓ)Se_{y}S_{2-y}. In one embodiment, the lower network 20b includes photovoltaic cells 226 that employ a PbSe photovoltaic material, the upper network 20a includes photovoltaic cells 22a that employ a CdSe/a-Si photovoltaic material, and a middle or intervening network 20c (FIGS. 10 and 11) includes photovoltaic cells 22c that employ an mc-Si photovoltaic material.

In one embodiment, the lower network 20b includes photovoltaic cells 22b that employ a mc-Si photovoltaic material, the upper network 20a includes photovoltaic cells 22a that employ a CuGaSe₂ photovoltaic material, and a middle or intervening network 20c (FIGS. 10 and 11) includes photovoltaic cells 22c that employ an CuIn_{0.8}Ga_{0.2}S₂ photovoltaic material. In one embodiment, the lower network 20b includes photovoltaic cells 22b that employ a CuInSe₂ photovoltaic material, the upper network 20a includes photovoltaic cells 22a that employ an a-Si photovoltaic material, and a middle or intervening network 200 (FIGS. 10 and 11) includes photovoltaic cells 22c that employ an a-Si photovoltaic material.

In sortie embodiments, some variants of these materials may be used as the two of the three photovoltaic materials. For example, Cu(InₓGa₁₋ₓ)Se_{y}S₂, can have a variety of bandgaps. Cu(InₓGa₁₋ₓ)Se_{y}S_{2-y} can be produced with a suitable bandgap for upper of middle photovoltaic materials with some values of x and y, and other values can be used to produce Cu(InₓGa₁₋ₓ)Se_{y}S_{2-y} with a suitable bandgap for the middle or bottom photovoltaic materials.

In some embodiments, network 20a can be monolithically formed or integrated. In some embodiments, network 20b can be monolithically formed or integrated. In some embodiments, network 20c can be monolithically formed or integrated.

The wafer-based materials, particularly the silicon-based wafer materials and many of the materials used to make the middle and/or lowest bandgap photovoltaic materials can be produced in bulk based on known semiconductor manufacturing techniques.

Some absorber materials utilize particular deposition techniques to yield high-efficiency solar cells and solar networks. Amorphous Si, for example, can be deposited primarily by using plasma enhanced chemical vapor deposition (PE-CVD) and to a lesser degree hot-wire CVD. Crystalline silicon cells are, however, formed from a melt and grown into a large rod-like crystal or polycrystal, known as a boule. The boule is then sliced into wafers.

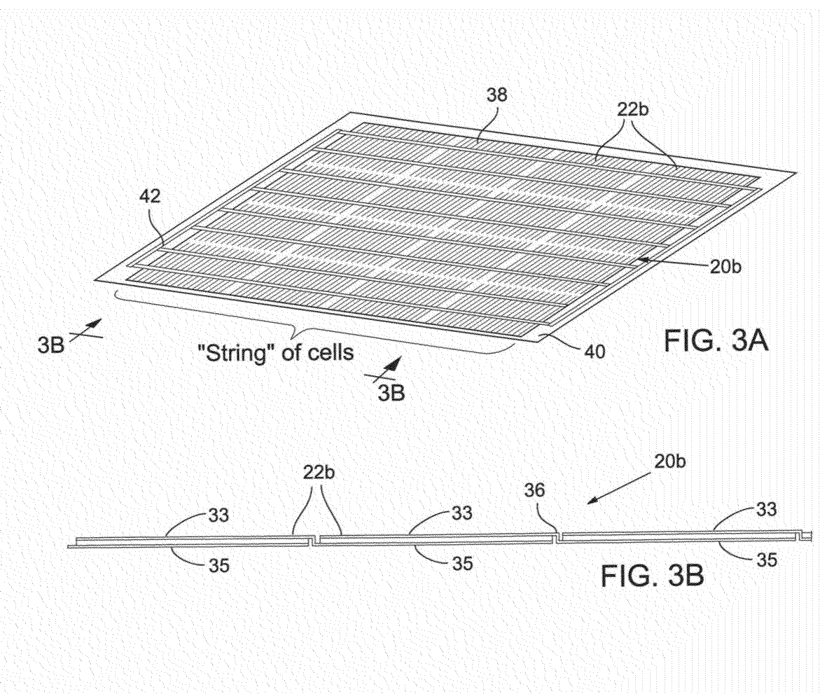

These materials can then be converted into photovoltaic materials based on inline, high-throughput, processing techniques. An exemplary processing scheme for converting mc-Si wafers into a network 20b, such as a hybrid integrated network of solar cells, is described below. The implementation and order of each step can vary slightly from material to material and process to process. FIGS. 3A and 3B are respective isometric and cross-sectional views of multiple wafer-based photovoltaic cells 22b electrically connected by cell interconnects 36 to form a wafer-based photovoltaic network 20b. With reference to FIGS. 3A and 3B, wafers are cut from bulk material and may have a damage layer resulting from a wafer sawing process. Wet chemistry, such as an alkaline etch, is used to remove the damage layer. A supplemental treatment, such as an acidic etch process, can also be applied to the wafer surface to create a light-scattering texture on the wafer to decrease its reflectivity.

A charge-separating junction, such as a p-n junction diode, is formed in the wafer to promote photovoltaic activity. For example, boron-doped, p-type mc-Si wafers are given a thin, phosphorus-doped, n-type Si top layer. Formation of the n-type layer occurs by application of a phosphorus-rich thin film onto the wafer surface and application of annealing temperatures on the order of 850° C. During the anneal process, phosphorus diffuses into the first few hundred nanometers (nm) of the Si wafer surface and becomes an electron-donating, n-type dopant in the Si wafer. The residual film on the wafer surface that acted as the phosphorus source is subsequently etched away with en acidic etch process.

To improve the light-trapping properties of the wafer material and to minimize surface defects that can hamper cell efficiency, a thin-film anti-reflective coating can be applied to the sun-facing surface with a chemical or physical vapor deposition process. An exemplary anti-reflective coating includes a single layer of silicon nitride with its thickness optimized to minimize reflection across the entire absorption spectrum of the photovoltaic material.

Screen printing of transparent conductive oxides or metal pastes is used in high-throughput cell fabrication processes to make electrical contact to the photovoltaic material. For example, on the sun-facing surface, an Ag paste is screen printed to contact the n-type Si in a grid pattern 38 that allows the photons of solar radiation to reach the Si for absorption in the wafer material. On the earth-facing surface, a blanket film of Al is printed to make a light-reflective, surface defect-passivating contact to the p-type material. Bus bars of Ag may also be printed on the earth-facing surface for easy cell interconnection in a photovoltaic module or solar panel. After each layer is printed, the wafer is sent through a drying oven to evaporate solvent and other liquids from the pastes.

Although the printing process dries the metal pastes to the top and bottom surfaces of the photovoltaic material, a short high-temperature anneal process is desirable to initiate intimate electrical contact with the p- and n-type regions of the photovoltaic wafer material. A typical anneal process, such as 900° C., is hotter than the drying processes.

A sawing, laser cutting, or chemical etching process can be employed to machine the edges of the wafers or photovoltaic cells 22b to ensure that their top and bottom layers are not electrically short circuited. After the cell fabrication process is completed, the current and voltage characteristics of the photovoltaic cells 22b are measured to calculate their efficiencies. Photovoltaic cells 22b of like efficiencies are binned together during a sorting process.

A reference describing the wafer fabrication process in more detail is Tool, C. J. J. et al., “17% mc-Si Solar Cell Efficiency Using Full In-Line Processing with improved Texturing and Screen-Printed Contacts on High Ohmic Emitters,” Proceedings of the 20th European Photovoltaic Solar Energy Conference. Barcelona, span, 6-10 Jun. 2005.

http/www.ecn.nl/docs/library/report/2005/rx05008.pdf

With reference again to FIG. 3A, in one embodiment, the photovoltaic cells 22b are arranged on a back sheet 40, tabbed with a tabbing material 42, and interconnected with solder or welding to form a network or module 20b. The cross sectional view presented in FIG. 3B illustrates a typical electrical series connection 36 of the photovoltaic cells 22b of the network 20b. The series connection from one photovoltaic cell 22b to the next is provided by soldering the tabbing material 42 to a top contact 33 of a photovoltaic cell 22b and then to a bottom contact 35 of a neighboring photovoltaic cell 22b. The electrical limitations of this series connection are analogous to the limitations of the series connection of the photovoltaic materials in monolithic epitaxial solar cells, and in both cases, the electrical current of the whole assembly is limited by the material or cell that produces the lowest photocurrent.

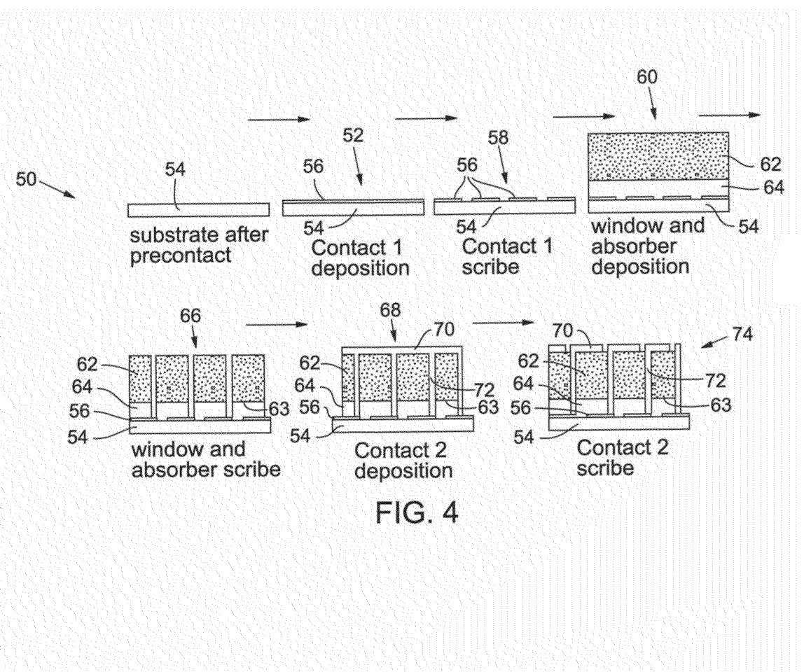

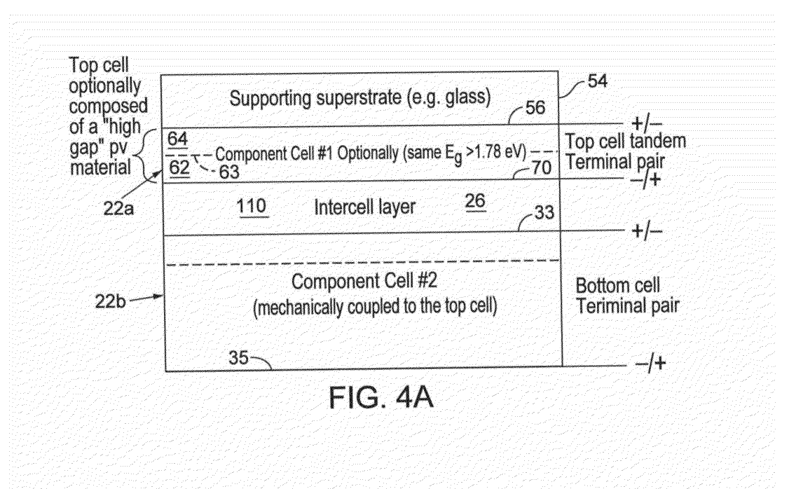

As noted earlier, the photovoltaic material of the higher bandgap network 20a is independently formed. The higher bandgap photovoltaic material is deposited on a large area substrate 54 (FIG. 4) by a high throughput process (e.g. PVD, CSS, evaporation/sublimation, or solution processing like printing). CdTe, for example, can be deposited in many different ways, but close-space sublimation (CBS) is the most prevalent. The most efficient cells based on thin-film copper indium gallium diselenide (CIGS) tend to be produced with evaporation. Many thin-film technologies economically benefit from the ability to be deposited onto very large substrates 54 (1 m×1.5 m to larger than 3 m×3 m) and then for the photovoltaic cells 22a to be monolithically defined and integrated. The network 20a is sometimes referred to as a monolithically integrated array of solar cells.

However, commercially available thin-film monolithically integrated arrays might not be good candidates for use as the networks 20a in a hybrid solar panel 24. Most commercially available thin-film monolithically integrated arrays have a reflecting bottom contact or bottom sheet behind the solar cells that is not transparent to any incident solar radiation. This reflective layer is either a protective conformal white sheet (such as Tedlar® by DuPont™) that reflects light back into the array of solar cells, or it is conductive and doubles as the bottom contact for the solar cells. For example, due to absorption range considerations, amorphous Si (a-Si) could work well as the photovoltaic material for the high bandgap network 20a, but most commercially available a-Si panels have a non-transparent, bottom reflector film. Although there are commercially available “bifacial” modules, where the top and bottom can face the sun and absorb light, the side designed to be the “bottom” is often heavily shaded by a contact pattern and would provide too much shadowing, of the bottom to be useful for a hybrid solar panel design.

FIG. 4 is a series of sectional views showing steps for a simplified process 50 for fabricating a thin-film network 20a. With reference to FIG. 4, in a process step 52, a first transparent conductor layer or contact 56 (also front, upper, to or sun facing contact 56) is deposited on a relatively transparent large substrate 54. (Because the to photovoltaic cell 20a may be manufactured by deposition of layers in an order opposite to the order of the layers in the sun-facing operational orientation of the top photovoltaic cell 20a, the first transparent conductor layer 56 may alternatively be referred to as the bottom contact during the manufacturing process.)

In a process step 58, the transparent conductor layer 56 is patterned through standard lithographic or other patterning techniques, in a process step 60, an optional “window” layer 64 (such as for some CdTe and CIGS systems) and an active absorber layer 62 of the photovoltaic material are sequentially deposited. The window layer 64 is a semiconductor thin film of opposite doping type as the absorber layer 62. The junction 63 between the window layer 64 and the absorber layer 62 causes charge carrier separation, determines the direction of current flow, and creates the diode that experiences the photovoltaic effect.

In a process step 66, the absorber layer 62 and the “window” layer 64 are patterned through standard lithographic or other patterning techniques, including laser or mechanical scribing, or photolithography, or inkjet printing. In a process step 68, a second transparent conductor material is deposited over the layers of the photovoltaic material and the “window” layer 64 to provide material(s) for second transparent conductor layers or contacts (or electrodes) 70 and cell interconnects 72. The second contacts 70 (also rear, lower, bottom, or earth-facing contact 70) and interconnects 72 may be formed from the same or different conductive materials. (Because the top photovoltaic cell 20a may be manufactured by deposition of layers in an order opposite to the order of the layers in the sun-facing operational orientation of the top photovoltaic cell 20a, the second contact 70 may alternatively be referred to as the top contact during the manufacturing process.) In a process step 74, the second transparent conductor material is patterned to form the second contacts 70 and complete the network 20a of photovoltaic cells 22a of the higher bandgap material. This thin-film production process 50 is an example of a monolithically integrated network 20a where the materials are all deposited into the large glass substrate 54 and patterning is done at the panel scale to define individual photovoltaic cells 22a rather than independent fabrication and piecewise placement as in wafer-based module technology.

In this embodiment, the patterned thin-film monolith forms the second network 20e of the hybrid solar panel 24, either after the patterning the active photovoltaic material or after deposition of the second electrical contact. The as substrate 54 used to support the thin-film material can form an outer layer (front or top layer) of the hybrid solar panel 24. An optical interlayer 26, such as a coupling material, with optional interconnects can be supported between the networks 20a and 20b. The final stack of the networks 20a and 20b and the interlayer 26 can be sealed and framed (however a frame is optional for some architectures) to form the hybrid solar panel 24.

As noted earlier, the decoupling of the fabrication of the different photovoltaic materials permits a number of advantages and opportunities. For example, there are some advantages for making the layers of thin-film photovoltaic materials to be optimally thin. However, the surface structure of standard top or front contacts used for standard mc-Si solar cells is irregular such that the topographical variations are on the same scale as, or often larger than, the desirable thickness of the thin-film layer. These divergent properties and objectives make production of monolithic multijunction solar cells or networks expensive or complicated. By decoupling the fabrication of networks 20a and 20b, the thickness of the photovoltaic material in network 20a can be optimized for performance characteristics independent from the constraints of the topography of network 20b. For example, in the case of a-Si thin-film cells, the thickness desired for efficient charge collection about 300 nm or less. The roughness on mc-Si solar cells is, however, often greater than 1 micron. These size characteristics make cc-optimization of the two cell components difficult if integrated monolithically.

The decoupling of the fabrication of the different photovoltaic materials also permits each of the photovoltaic materials to be optimized to absorb different regions of the solar spectrum without regard to the fabrication techniques used to make the other photovoltaic material.

For example, the performance of crystalline silicon solar cells is very sensitive to fabrication techniques that expose it to elevated temperatures after the fabrication of the silicon photovoltaic layers is finished. At elevated temperatures, impurities such as from newly applied layers can rapidly diffuse through the silicon, modifying its junction profile. Also stresses due to thermal mismatch can cause bowing which results in higher breakage rates of the wafer substrates. These issues present challenges when trying to build an epitaxial multijunction architecture using crystalline silicon as the low bandgap photovoltaic material. Many thin-film systems, such as CdTe, CuGaSe₂ (CGS), CIGS, and CdSe, all require substrate temperatures over 400° C. which can result in degradation of the underlying photovoltaic silicon portion when grown directly on top of it. Furthermore, corrosive treatments, such as selenizations, CdCl₂, etc., which are desirable to achieve good performance of the thin-film photovoltaic portion would be detrimental to the electronics of the underlying silicon. Therefore, it is advantageous to decouple the fabrication of the two photovoltaic materials and to assemble networks of the component cells rather than to monolithically grow one on to of the other.

Thus, in a specific example, multicrystalline silicon (mc-Si) is used as the low bandgap photovoltaic material (produced by a wafer-based technology where 6″×6″ (15 cm×15 cm) wafers undergo mostly in-line high-throughput processing as previously discussed) to provide a low bandgap network 20b, and a thin-film photovoltaic material, such as a-Si, CdTe, CGS, CdSe, is used as the high bandgap photovoltaic material (produced by evaporative and lithographic processes previously discussed) to provide a high bandgap network 20a. The two networks 20a and 20b of incompatibly produced photovoltaic materials 22a and 22b are then electrically connected to form a hybrid solar panel 24 of photovoltaic materials 22a and 22b that could not be used together in an epitaxially grown multijunction solar cell. Each of the component networks 20a and 20b are formed from low-cost methods, usually considered to be mutually exclusive. Integration at the panel level adds only a marginal cost. The two-network architecture could easily be modified to include any number of networks 20 and any number of photovoltaic materials and can be produced by a variety of manufacturing methods. This hybrid multijunction technology can also easily be scaled to produce low-cost high-efficiency hybrid solar panels 24 of any size. This example of thin-film-on-silicon technology integrated at the panel level is just one implementation of a very general methodology.

FIG. 4A is a schematic diagram of an exemplary photovoltaic module 44, such as a two-network photovoltaic module 44, that includes one or more photovoltaic cells 22a of the network 20a and one or more photovoltaic cells 22b the network 20b. With reference to FIG. 4A, the photovoltaic cells 22a include a photovoltaic material having a junction 63 positioned between a first pair of spaced apart front and rear electrically conductive layers 56 and 70. The photovoltaic cells 22b include a different photovoltaic material having a junction 46 positioned between a second pair of spaced apart front and rear electrically conductive layers 33 and 35. The optical interlayer 110 is positioned between the photovoltaic cells 22e and 22b.

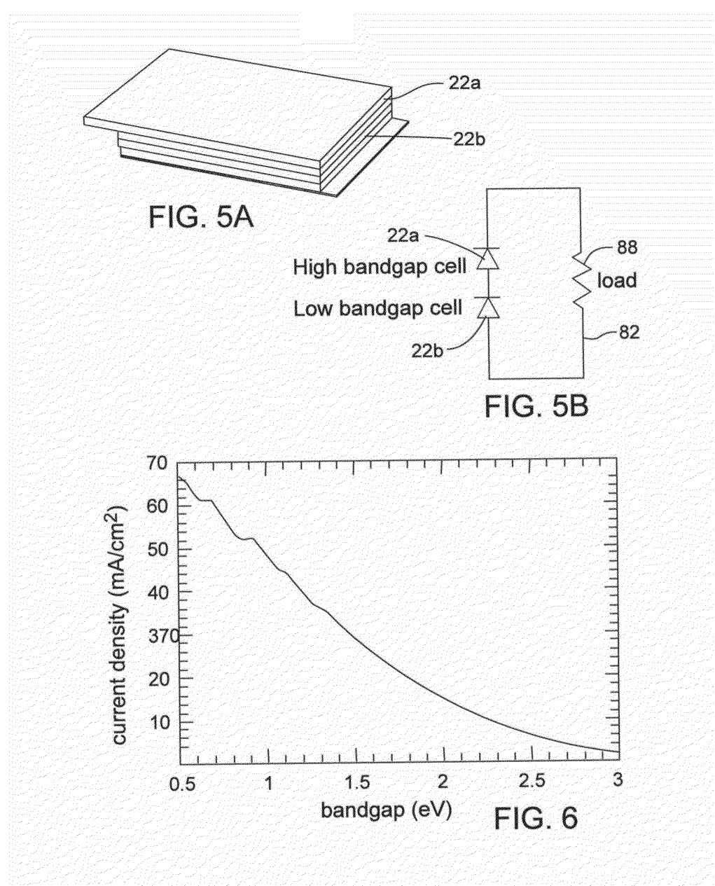

FIG. 5A is an isometric view of a multijunction stack 80 wherein the high bandgap photovoltaic cell 22a has the same surface area dimensions as the surface area dimensions of the underlying low bandgap photovoltaic cell 22b and wherein the photovoltaic cells 22a and 22b are electrically connected in series. FIG. 5B is a circuit diagram 82 representing the electronic configuration of the photovoltaic cells 22a and 22b of FIG. 5A. With reference to FIGS. 4A, 5A, and 5B, the electrical series connection is the only connection available to epitaxially grown multijunction solar cells; however, the electrical series connection is only one option for connection between the photovoltaic cells 20a and 20b of the photovoltaic networks 20a and 20b.

When utilizing the power generated by this stack 80, a top electrode 84 of the high bandgap photovoltaic cell 22a and a bottom electrode 86 of the low bandgap photovoltaic cell 22b act as terminals in a battery and the power generated can drive a load as shown in the simplified circuit diagram 82 where the photovoltaic cells 22a and 22b are represented as diodes and the load 88 is represented as a resistor. When connected in this way, a closed circuit 90 is formed. Because there is only one flow path in the circuit 90 for current that is produced by the photovoltaic cells 22a and 22b, the maximum current that can run through the circuit 90 is the lowest current generated by either of the two photovoltaic cells 22a and 22b. If for example, the low bandgap photovoltaic cell 22b produces 3 amps; and the high bandgap photovoltaic cell 22a produces 2 amps, only 2 amps can be used to drive the load 88. The extra 1 amp of current produced by the low bandgap photovoltaic cell 22b cannot flow through the circuit 90, and its energy will be lost as heat because the high bandgap photovoltaic cell 22a limits the amount of current that can flow through the circuit 90. The heat may additionally adversely affect the absorption capability of either of the photovoltaic cells 22a and 22b, adversely affect their conversion efficiencies, or adversely affect both absorption and conversion in one or both of the photovoltaic cells 22a and 22b. Thus, for an electrical series configuration between the photovoltaic cells 22a and 22b, they should preferably generate the same amount of current to avoid wasting energy and to achieve greater efficiency.

However, because the solar spectrum comprises photons of different energies, photovoltaic cells 22 made of different materials with different bandgaps will generate different amounts of current. Because the efficiency of a photovoltaic cell 22 is directly proportional with the current it produces, losses due to current mismatch between two stacked photovoltaic cells 22 can readily be estimated. FIG. 6 is a graph of the maximum current density a photovoltaic cell 22 can generate as a function of its bandgap under AM1.5G sunlight. (AM1.5G represents the standard spectrum of sunlight at the Earth's surface where G stands for “global” and includes both direct and diffuse radiation and the number “1.5” indicates that the length of the path of light through the atmosphere is 1.5 times that of the shorter path when the sun is directly overhead) With reference to FIGS. 5A, 5B, and 6, FIG. 6 can be used to explain further limitations of the electrical series configuration of the multifunction stack 80. For example, if the photovoltaic cells 22a and 22b each have a surface area of cm² and the photovoltaic cell 22a has a photovoltaic material with a bandgap of 2.5 eV, then this photovoltaic cell 22a, with no loss of current to recombination, could produce a maximum current of 6.2 mA. Such a photovoltaic cell 22a could represent the high bandgap photovoltaic material. Typical silicon photovoltaic material, on the other hand, has a bandgap of −1.1 eV. The maximum current a stand-alone silicon photovoltaic cell 22b could produce is about 44 mA. If a silicon photovoltaic cell 22b represented the low bandgap photovoltaic material in FIG. 5A, then the photovoltaic cell 22a could filter out 6.2 mA of current, so the filtered silicon photovoltaic cell 22b could produce only 39.8 mA. If these photovoltaic cells 22a and 22b were connected monolithically in series as shown in FIG. 5A, the multifunction stack 80 would only produce 5.2 mA of current because the current of the photovoltaic cell 22a is limiting. In this example, the high bandgap photovoltaic cell 20a is limiting.

As another example, a high bandgap top photovoltaic cell 22a could have a bandgap of 1.5 eV. This photovoltaic cell 22a could then produce 29 mA. The silicon photovoltaic cell 22b filtered by this photovoltaic cell 22a could produce up to only 15 mA. If these photovoltaic cells 22a and 22b were connected monolithically in series as shown in FIG. 5A, the multijunction stack 80 would only produce 15 mA of current because the current of the photovoltaic cell 22b is limiting.

Thus, for a bottom photovoltaic cell 22b of a given photovoltaic material in a multijunction stack 80 in a series configuration, there is an optimal bandgap for the photovoltaic material of the top photovoltaic cell 22a that would exactly match currents such that neither the top photovoltaic cell 22a nor the bottom photovoltaic cell 22b would be limiting. For a bottom photovoltaic cell 22b of silicon photovoltaic material in a multijunction stack 80 in a series configuration, the optimal photovoltaic material of the top photovoltaic cell 22a top cell would have a bandgap that gave 0.5×(44 mA/cm²)=22 mA/cm², which corresponds to a bandgap of ˜1.7 eV. Hence, when a multijunction stack 80 is epitaxially made, there is one and only one bandgap for a top photovoltaic cell 22a that can provide the optimal current to match that of the bottom photovoltaic cell 22b. A current density mismatch (for same-sized photovoltaic cells 22) of more than 5%, between photovoltaic cells 22a and 22b is generally unacceptable for an eptiaxial multifunction stack 80. These factors put large constraints on the choice of photovoltaic materials that can be used for the top photovoltaic cell 22a.

Because of the current matching limits mentioned above, simply wiring the networks 20a and 20b together in series when stacked on top of each other would cause the stack to supply only the current of the network 20 with the least current. For instance, SunTech amorphous silicon panels are reported in datasheets to supply 1.2 A of current at max power point (MPP); and solar panels made of 156 mm×156 mm mc-Si wafers supply over 7 A of current under full illumination at MPP. So, even if the optics of the aggregate panel were configured to maximize transmission of long wavelength light to the bottom panel, the current of that panel would still be limited because of the lower current of the top panel.

However, the size and/or the number of photovoltaic cells 22 in each network 20 can be different, and a variety of interconnection schemes are possible rather than a simple series connected multijunction stack 80. Thus, any current mismatch for same sized photovoltaic cells 22a and 22b could be compensated by selecting the surface area dimensions of the photovoltaic cells 22a and 22b such that the currents match to within 15% or the currents differ by less than 15%. In some embodiments, the currents generated by the photovoltaic cells 22a and 22b match to within 10% or the currents differ by less than 05%. In some embodiments, the currents generated by the photovoltaic cells 22e and 22b match to within 5% or the currents differ by less than 5%. In some embodiments, the currents generated by the photovoltaic cells 22e and 22b match to within 1% or the currents differ by less than 1%.

Additionally, the networks 20a and 20b are not restricted to a simple parallel only connection. The decoupling of one-to-one connections between the photovoltaic cells 22 of the different networks 20 also facilitates the use of high volume optimized manufacturing processes unique to each network 20, integration of the coupling of the photovoltaic cells 20 is then done at the network level.

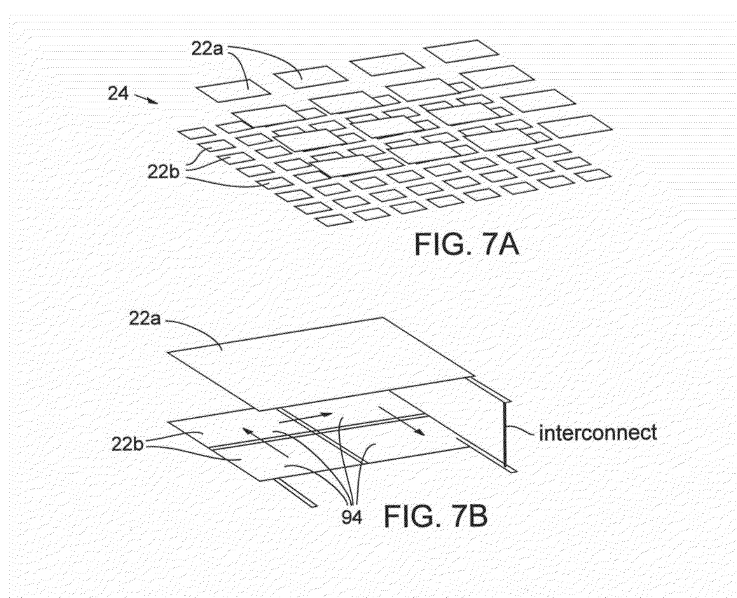

FIG. 7A is an isometric view of a hybrid solar panel 24 having the photovoltaic cells 22a and 22b of the networks 20a and 20b interconnected in an exemplary cooperative hybrid electronic configuration. FIG. 7B is an isometric view of an enlarged portion of FIG. 7A, showing the electronic interconnections of the photovoltaic cells 22a and 22b in the networks 20a and 20b. With reference to FIGS. 7A and 7B, some or all of the photovoltaic cells 22a of the network 20a can be electronically wired in series and some or all of the photovoltaic cells 22b of the network 20b can be electronically wired in series, instead of electronically wiring every pair of the photovoltaic cells 22a and 22b together only in series as is done in multifunction stack 80.

In one example, the photovoltaic cells 22b are made from a silicon photovoltaic material that produces about 30 mA/cm² (when decoupled from the top network 20a having photovoltaic material that absorbs a portion of the short wavelength photons). When coupled with the photovoltaic cells 22a that absorb some of the photons that would otherwise be absorbed by the silicon photovoltaic material in the stand-alone silicon photovoltaic cells 22b, the silicon photovoltaic cells 22b produce only 20 mA/cm². The photovoltaic cells 22a made from a thin-film photovoltaic material, of the same size as the photovoltaic cells 22b in this example, produce only about 10 mA/cm². However, the photovoltaic cells 22a are made to have a surface area that is two times larger than the surface area of the photovoltaic cells 22b, and the network 206 has two times as many of the photovoltaic cells 22b as the network 20a has of the photovoltaic cells 22a. The two underlying photovoltaic cells 22b are wired in series as represented by arrows 94 to produce about 2250 mA, and the group of them is connected in series to the single larger photovoltaic cell 22a, which also produces 2260 mA, thereby matching the currents of the two optically connected networks 20a and 20b so that they can be connected in series without sacrifice of the current generated by either of the networks 20a or 20b.

In addition to or an alternative to having harmonized current density, the networks 20a and 20b cooperate more efficiently when their voltage potentials are harmonized in the module 24. In one example, the photovoltaic cells 22b are made from a silicon photovoltaic material that produces about 0.5V per cell when coupled with the photovoltaic cells 22a. The photovoltaic cells 22a, made from a thin-film photovoltaic material for example, produce 1 V per cell. Since voltages add in series and are independent of cell area, the photovoltaic cells 22b are made to have a surface area that is two times smaller than the surface area of the photovoltaic cells 22a, and the network 20b has two times as many of the photovoltaic cells 22b as the network 20a has of the photovoltaic cells 22a. The two underlying photovoltaic cells 22b are wired in parallel as represented by arrows 94 to produce about 1V and the group of them is connected in series to the single larger photovoltaic cells 22a, which also produces 1V, thereby matching the currents of the two optically connected networks 20a and 20b so that they can be connected in series without sacrifice of the voltage generated by either of the networks 20a or 20b.

Additionally or alternatively, the networks 20a may be arranged from one or more strings of electrically connected photovoltaic cells 22a and the networks 20b may be arranged from one or more strings of electrically photovoltaic cells 22b. The number of photovoltaic cells 22 in each string may be selected to optimize performance, the number of strings connected together in a network 20 may be selected to optimize performance, and the electrical nature of the connections (series or parallel) may be selected to optimize performance.

As noted earlier, the patterning of all materials or layers can be done monolithically to form interconnections between the photovoltaic cells 22a to form the integrated network 20a. This kind of interconnection allows great flexibility in the selection of interconnection schemes and geometry. These interconnection schemes and geometry can be readily adapted to suit changes in materials or sizes of the photovoltaic cells 22a. Changing the interconnection scheme of a hybrid network (where each photovoltaic cell 22 is individually positioned and mechanically strung to adjacent photovoltaic cells 22) would involve changing multiple tools, whereas changing interconnection schemes and geometry for an Integrated network 20a involves swapping out masks or scribe raster programs. Additionally, the high precision offered by laser scribing techniques allows the patterning of very small features that can enhance the efficiency of monolithic integration of the networks 20a.

In addition to permitting a variety of interconnect schemes and geometries, the hybrid solar panel 24 allows for greater selection of interconnect materials. For example in traditional epitaxial and monolithic solar cell fabrication, the contacts are made (between to and bottom soar cell subcomponents) through an electrically active interlayer that must be compatible with the fabrication processes of both the subcomponent materials.

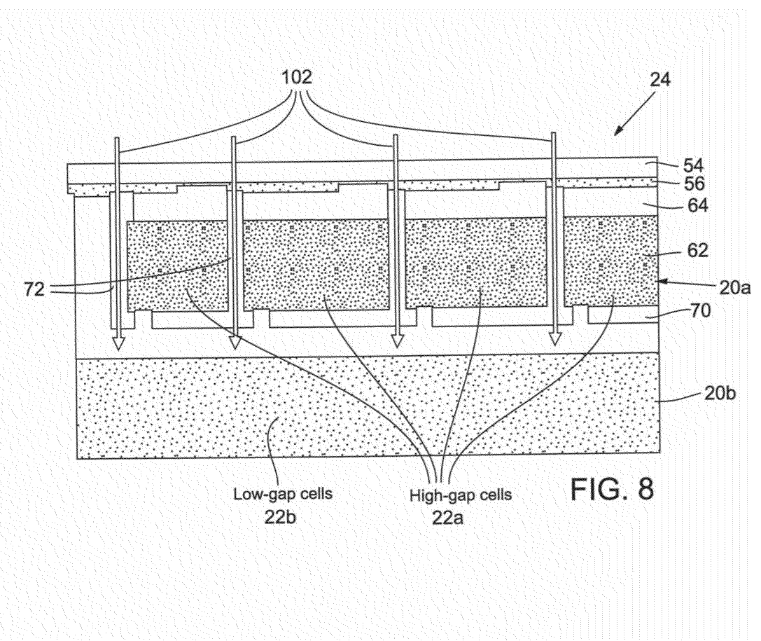

The hybrid solar panel 24 not only allows greater flexibility in material choice for photovoltaic materials, but also allows greater flexibility (and may introduce additional selection criteria) for the interconnect materials beyond those that may be considered for stand-alone thin-layer solar networks. Both the interconnect material and the geometry of the to network 20a can be tailored to transmit photons incident on the interconnect material to the photovoltaic cells 22b of the underlying low bandgap network 20b. In particular, it is desirable for the interconnects 72 to be conductive enough to minimize power loss to resistive heating of the interconnects 72 while not significantly blocking light from reaching the o bandgap network 20b. Thus, in some embodiments, the interconnect material is transparent or semi-transparent to a major portion of, or all of the wavelengths of the primary light absorption spectrum of the photovoltaic material of network 20b. FIG. 8 is a cross-sectional view of a simplified hybrid solar panel 24 showing transmission of light 102 through the cell interconnects 72 that connect a high bandgap network 20a to a low bandgap network 20b.

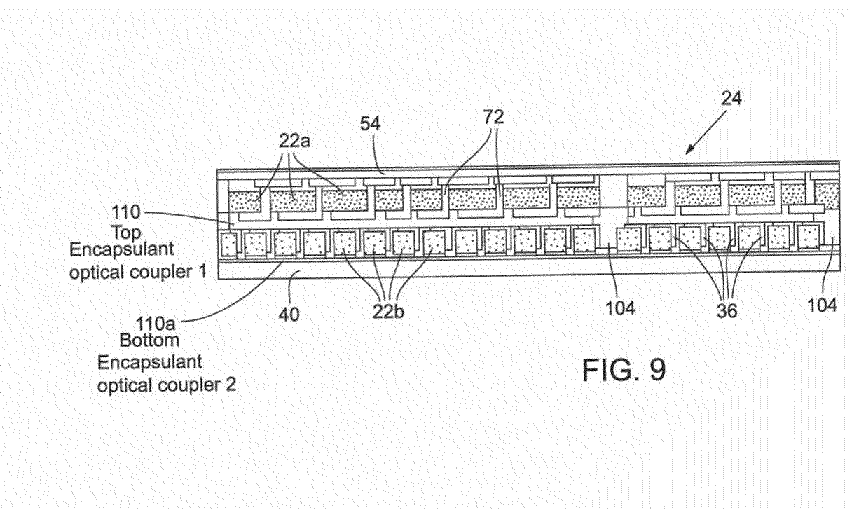

FIG. 9 is as cross-sectional view of a hybrid solar panel 24 showing an exemplary network interconnect 104 between the high bar gap network 20a and the low bandgap network 20b With reference to FIG. 9, the network interconnects 104 may share similar geometric and material selection criteria as those used for the cell interconnects 72. Alternatively, the network interconnects 104 may utilize additional or different geometric and material selection criteria as those used for the cell interconnects 72. For example, the interconnect material of the network interconnects 104 need not be partly or wholly transparent to wavelengths in the region of the primary absorption spectrum of the photovoltaic material of the high bandgap networks 20a because the network interconnects 104 are positioned beneath the high bandgap networks 20a. In such embodiments, the properties of interconnect material of the network interconnects 104 can be optimized for conductivity or for transmission of wavelengths in the region of the primary absorption spectrum of the photovoltaic material of the low bandgap networks 20b at the expense of transmissivity to wavelengths in the region of the primary absorption spectrum of the photovoltaic material of the high bandgap networks 20a. In some embodiments, interconnect material of the network interconnects 104 can be made to be intentionally reflective to wavelengths in the region of the primary absorption spectrum of the photovoltaic material of the high bandgap networks 20a to provide the photovoltaic cells 22a an additional opportunity to absorb photons, having those wavelengths, that are incident on the network interconnects 104. In some embodiments, the network interconnects 104 are optimized for transmissivity to wavelengths in the primary absorption spectra of the photovoltaic materials of both the photovoltaic cells 22a and 22b to permit reflections off the back plate 40 to reach the network 20a.

The network interconnects 104 can be fabricated in processes similar to those used for monolithic devices, in some embodiments, the network interconnects 104 can additionally or alternatively be used for connection via the perimeter of the networks 20a and 20b. The same interconnect material can also be used for additional electrical elements such as bus interconnects which act to interconnect top strings of photovoltaic cells 22a with bottom strings of photovoltaic cells 22b rather than cell-by-cell interconnection. Such structures can reduce resistive losses and thereby increase efficiency.

Top contacts also are subject to similar geometric and light transmissivity considerations. Transparent conductive oxides (TCOs) used in the solar cell and flat panel display industries have the unfortunate property of absorbing a portion of long wavelength light due to a process called free-carrier absorption. This absorption process increases super-linearly as wavelength increases. In particular, the TCOs absorb light in the wavelength range of solar radiation in which the exemplary mc-Si bottom photovoltaic cells 22b operate. Thus, the efficiency of the bottom photovoltaic cells 22b is therefore going, to be affected by overlying contacts. This problem is enhanced when both the top and bottom electrical contacts 56 and 70 of the top photovoltaic cells 22a of the top network 20a are made of the TCO materials. The magnitude of a TCO's long wavelength absorption scales with the conductivity of the layer. Stand-alone films of TCOs such as aluminum doped zinc oxide (AZO) or fluorine doped tin oxide (FTO) can absorb as much as 20-30% in the wavelength range of 750 to 1200 nm. Due to reflections off of multiple interfaces, this problem is made worse when the TCOs are incorporated into the photovoltaic cells 22a of the top photovoltaic network 20a, and absorbance by the TCO can increase to 50 to 60%. Therefore, special design considerations for those TCOs are desirable to minimize absorption of light that would otherwise power the photovoltaic cells 22b of the bottom network 20b.

A potent solution to TCO absorbance problems is thinning the TCO layer down to half or one-quarter of the thickness used in stand-alone solar networks. For example, the thickness of contacts 56 and 70 can be less than 2 μm. In some embodiments, the thickness of one or both contacts 56 and 70 can be less than 1 μm or less than 500 nm. In some embodiments, the thickness of one or both contacts 56 and 70 can be less than less than 200 nm. In some embodiments, the thickness of one or both contacts 50 and 70 can be about 100 nm, plus or minus 50 nm. Although a stand-alone thinner TCO layer might be unable to support nigh current levels without adding resistive power losses, a thinner TCO combined with a metal grid electrode can handle larger currents with low resistance.

In some embodiments, the TCO layer of the front contact 56 has a sheet resistivity of less than 200 Ohms/square, and the TCO layer of the front contact 56 (or the TCO layer plus metal gridline) has transmission properties of greater than 85% of the light in the wavelength range of 300-900 nm and greater than 65% of the light in the wavelength range of 900-1200 nm.

In some embodiments, the TCO layer of the bottom contact 70 has a sheet resistivity of less than 200 Ohms/square and has transmission properties of greater than 66% of the light in the wavelength range of 700-1200 nm.

A TCO layer may include, but is not limited to, one or more of the following materials, tin-doped indium oxide (ITO), fluorine doped tin oxide (FTO), aluminum-doped tin oxide (ATO), indium-doped cadmium oxide (ICO), or a doped zinc oxide, such as aluminum-doped zinc oxide (AZO). Alternatively the transparent conductive layer ma include carbon nanotube networks, graphene, or networks of polymers such as poly(3,4-ethylenedioxythiophene) and its derivatives.

In some optional, alternative, or additive embodiments, the TCO includes a polycrystalline metal oxide with a charge carrier mobility of 10 to 100 cm²/Vs and a carrier density greater than 10¹⁹ cm⁻³. In some such embodiments, the polycrystalline metal oxide has a charge carrier mobility of between 25 and 75 cm²/Vs. In some embodiments, the polycrystalline metal oxide has a charge carrier mobility of greater than 60 cm²/Vs. In some embodiments, the polycrystalline metal oxide has a charge carrier mobility of less than 30 cm²/Vs. In some such embodiments, the polycrystalline metal oxide has a carrier density greater than 10¹⁹ cm⁻².

With reference again to FIG. 9, if the top high bandgap network 20a having adequate transparency at long wavelengths is placed directly above the low bandgap network 20b with an air gap between the two networks 20a and 20b, the large refractive index difference between air and the photovoltaic material of the photovoltaic cells 22a may cause high reflection of long wavelength photons at the air interface so that many of the long wavelength photons never reach the low bandgap network 20b, decreasing the amount of long wavelength photons available to be absorbed by the photovoltaic cells 22b and reducing the amount of current that can be generated by the low bandgap network 20b. The problem is improved only slightly when the air gap is replaced with an interlayer of homogenous material having a refractive index similar to that of glass.

As noted earlier, the multijunction concept is typically manifested in a cell architecture where the individual cells are monolithically stacked and all grown using the same process (e.g. all MOCVD, or all PECVD, etc). Also common in these monolithic multijunction cells is a direct series connection between component cells such that current matching and limiting occurs. The series connection between component cells is usually a thin layer that is optimized for charge collection and transport and plays little to no beneficial role in the optical design of the overall monolithic multijunction cell. Moreover, this layer can somewhat hinder the optical design of the monolithic multijunction cell by providing pathways for absorption and reflection of photons so that they cannot be extracted and counted as current. More specifically, these layers, often referred to as tunnel junctions or recombination junctions, usually employ highly doped semiconductors with absorption onsets similar to those of the upper photovoltaic materials of the monolithic multijunction cells. Therefore, these layers can decrease the photon density in the overall the monolithic multifunction cell by absorbing light via inter- or intraband electronic transitions.

Another, less common, scheme for multi junction integration involves the mechanical stacking of the component cells, in this integration method, cell interconnection and optical coupling occur at the module level and relatively thick materials such as cell tabbing wire and encapsulation sheets are used to complete the multijunction cells. The medium separating the component cells in the tandem stack is homogenous and is often a low refractive index insulator that just minimizes single-interface reflection due to refractive index mismatch, (See Matsumoto. Y at al, “a-Si/poly-Si two- and four-terminal tandem type solar cells,” Conference Record of the 21st IEEE PVSC, 21-25 May 1990, page 1420.)

In some cases, this optical couple can even be an air gap, and any sort of anti-reflective measures are implemented at the component cell level. (See Takamoto, T, at al, “InGaP/GaAs and in GaAs mechanically-stacked triple-junction solar cells”, Conference Record of the 26th IEEE PVSC, Sep. 30-Oct. 3, 1997, page 1021.) Such optical designs lead to a decrease in the amount of light trapped by the top cell as well as a decrease in the amount of light transmitted to lower cells, due to reflection off of various interfaces in the top cell. The improper balance of light between the component cells can lead to issues with current matching in series-connected architectures and power conversion efficiency losses due to low current generation. This improper balance of light absorption between cells also leads to constrained optimization of the component cells. Tandem architectures often employ cells with large, non-optimal thicknesses in attempt to trap and absorb more of the incident radiation. Component cells with thicker active regions produce more current, but generally at the expense of open circuit voltage losses. Thinner cells generally have higher open circuit voltages because the electric fields within the cell layer are larger and because thinner layers exhibit less recombination, that is, all carriers are generated closer to the active junction and are available for extraction.

Thus, some embodiments aim to displace a homogenous intercell layer in a mechanically stacked multijunction tandem cell with an optically engineered optical interlayer 110 that can maximize light collection by both of the component cells that surround and can also ad in properly spiting the spectrum and balancing the current density output of the component cells for series connection and enable thinner component cell active layers, which can act to decouple the competing maximizations of light absorption/current generation and open circuit voltage.

For example, in traditional monolithic compound semiconductor or thin-film silicon“micromorph,” tandem solar cell systems, the interlayer serves both to tune the amount of fight absorbed by the top and bottom solar cell components as well as to provide electrical connection between the solar cell components via a tunnel-contact.

The interlayer between the photovoltaic materials in such monolithic multifunction cells is therefore an optically thin inorganic, electrically conductive layer that has similar refractive index to the photovoltaic materials that the interlayer is connecting in series. Deposition processes require the layer to remain much narrower than 1000 nm in thicknesses and generally narrower than 150 nm (typically in the 10-50 nm range). These features strongly constrain the material used for the interlayer for multijunction solar cells grown epitaxially and the degree to which their interlayers can be optically engineered. For example, to effectively grade indices of refraction to minimize boundary reflections, the refractive index should preferably slowly change over a distance of microns or larger. The thickness limitation of the interlayer for multijunction solar cells grown epitaxially substantially reduces the usefulness of refractive index grading.

However, the geometric and compositional characteristics of an optical interlayer 110 between the networks 20a and 20b of the hybrid solar panel 24 can be better selected to optimize the optical coupling properties of the optical interlayer 110, such as its refractive index profile, to minimize reflection of long wavelength photons. With respect to the hybrid solar panel 24, the optical interlayer 110 need not be conductive, need not be limited to nanometer scale thicknesses, and need not participate in the electrical or physical interconnection of the photovoltaic cells 22a and 22b in individual stacks. In particular, the optical interlayer 110 does not have to participate in charge collection or transport from the photovoltaic cells 22a to the photovoltaic cells 22b (or the reverse) and therefore can be of arbitrary thickness and composition.

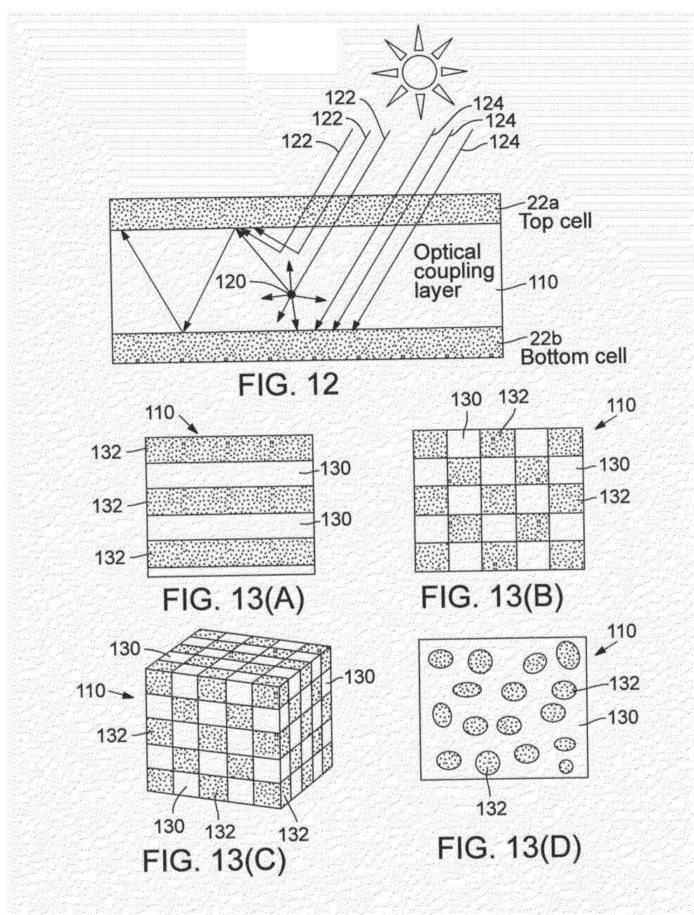

Leveraging design guidelines, engineering, and optical phenomena from the optical filter industry, the optical interlayer 110 can include multiple layers of thin films to engineer the transmission and reflection of various parts of the solar spectrum. The optical interlayer 110 can be an organic or inorganic material and possess a refractive index profile that will act as a light trapping and redistribution layer. In some embodiments, the optical interlayer 110 aids in splitting the solar spectrum and coupling the relevant radiation into the photovoltaic cells 22 of the respective networks 20. Light diffraction, refraction, reflection and scattering phenomena can be exploited in the design of the optical interlayer 110 to maximize the amount of light trapped in the appropriate photovoltaic cells 22. For example, the optical interlayer 110 can re-disperse short wavelength light back into the high bandgap photovoltaic material of the photovoltaic cells 22a, aid in coupling of reflected longer wavelength light back into the low bandgap photovoltaic material of the photovoltaic cells 22b, or perform both functions. FIG. 12 is an enlarged sectional side view of a portion of two-junction photovoltaic panel showing selective light reflection by the optical interlayer 110. With reference to FIG. 12, a composition 120 of the optical interlayer 110 selectively reflects, transmits, or downshifts incident light so that it is directed (directly or indirectly) to the appropriately absorbing photovoltaic material. Moreover, in one embodiment; the optical interlayer 110 is positioned between two networks 20 in a two-Junction module 24 to selectively reflect and backscatter unabsorbed light back to the photovoltaic cells 22a (optimized for UV-visible absorption) of the upper network 20a and allows the rest of light to pass to the photovoltaic cells 22b (optimized for the near-IR absorption) of the lower network 20b. Arrows 122 represent reflected paths of short wavelength light, and arrows 124 represent unreflected paths of long wavelength light.

In some embodiments, the coupling performance of the optical interlayer 110 can be optimized by techniques such as grading the refractive index as a function of depth in the optical interlayer 110 or combining multiple layers of different refractive indices to enhance transmission.

For example, unlike the interlayer in monolithically grown structures, the optical interlayer 110 can be significantly thicker than the wavelengths of light of either of the regions of primary light absorption spectra of the photovoltaic cells 22a and 22b. The thickness for the optical interlayer 110 can range from a few nanometers to multiple millimeters. The optional thickness over about 150 nm permits optical structures to be incorporated into the optical interlayer 110. Such optical structures can include one or more of scattering- or light-emitting particles embedded in a matrix, 1-, 2-, and 3-dimensional gratings, and photonic crystals, all of which would be impractical, if not impossible, to incorporate into a multifunction solar cell grown monolithically. In particular, the optical interlayer 110 permits arbitrary variation of refractive index in 1, 2 or 3 dimensions to guide light directly and diffusely towards the photovoltaic cells 22 that are optimized for absorption of a particular part of the solar spectrum.

FIGS. 13A, 13B, 13C, and 13D are respective plan, plan, perspective, and sectional views of respective one-dimensional, two-dimensional, three-dimensional, and three-dimensional exemplary refractive index embodiments of the optical interlayer 110. With reference to FIG. 13, the optical interlayer 110 can be an optically thick film that employs ordered, periodic, and/or random variations in optical refractive index. The optical phenomena these variations assist in achieving are: 1) scattering of all wavelengths into totally internally reflected (TIR) light rays, 2) increased, tunable, and wavelength selective reflection 3) increased, tunable long wavelength transmission, and 4) wavelength tunable light absorption and re-emission for shifting the effective wavelength of the light radiation.

These optical phenomena all act to increase light trapping within the desired active layers of the photovoltaic materials of the photovoltaic cells 22a and 22b of the networks 20a and 20b, permitting the current densities to be more finely balanced between the photovoltaic cells 22a and 22b or the networks 20a and 20b. Design cues and optical filters used in laser and cosmological optics can be leveraged in the optical design of the optical interlayer 110.

With reference again to FIG. 13, the unhatched areas represent low refractive index materials 120, and the hatched areas represent high refractive index materials 132. FIG. 13A presents an example of a one-dimensional variation, which is similar to a grating. FIG. 13B presents an example of two-dimensional variation. FIG. 13C presents an example of an ordered three-dimensional variation. FIG. 13D presents an example of a disordered or random three-dimensional variation.

The optical interlayer 110 can additionally or alternatively address or enhance a number of optical phenomena. The optical interlayer 110 can enhance scattering to increase (total internal reflection (TIR) of incident light. Introduction of large differences in refractive index between a component and matrix material within a layer can give rise to an increased amount of light scattering. This scattering can lead to TIR, which increases the effective optical path length of fight inside the optical interlayer 110 and leads to more reflections off the ton and bottom interfaces of the layer. More interfacial reflections means that the light rays have more than one chance to enter the photovoltaic cells 22 above or below the optical interlayer 110, leading to an overall reduced optical reflectance and a greater fraction of light absorbed in the photovoltaic cells 22 that can be converted to electrical current. The result of this concept is similar to the result of texturization of single junction photovoltaic cells, wherein the texturization of the outer surface causes light to scatter at the cell/encapsulant interface and leads to lower reflectance. This optical property can be useful at all wavelengths at which the photovoltaic cells 22 surrounding the optical interlayer 110 absorb.

The optical interlayer 110 can enhance wavelength-tunable reflection. A multilayer optical film can be integrated into the optical interlayer 110 to provide tunable, selective reflection of shorter wavelength light back into the photovoltaic cells 22a of the top network 20a. This multilayer film is similar to a bandpass filter, where the passband wavelength, bandwidth, and primary incidence angle can be adjusted for optimal coupling with the photovoltaic material of the top network 20a. Desirable wavelength ranges for this reflection band are 400-600 nm with a preferred range of 300-710 nm for back reflection to the photovoltaic material of the top network 20a. Idealized angle dependence is 0% change in reflectance and thus current collection over 180 degrees of incidence, and necessary is no more than 30% power loss due to changes in reflectance and light absorption over that 180 degrees.

The optical interlayer 110 can enhance long wavelength transmittance. Similar multilayer stacks of films can be used to also increase the fraction of long wavelength light that is transmitted to the photovoltaic material of the bottom network 20b. This effect is similar to that observed for long pass filters, where transmission is maximized for long wavelength light, and short wavelength light is almost entirely rejected. The transmission turn-son wavelength and angle dependence of the transmission can be engineered by changing the design of the film stack, for example by integrating the appropriately-designed multilayer quarter-wave thin-film stack into the optical coupling layer.

Desirable wavelength ranges for this transmission band are 800-1000 him with a preferred range of 710-1200 nm for back reflection to the photovoltaic material of the bottom network 20b. Idealized angle dependence is 0% change in average transmission over 180 degrees of incidence, and necessary is no more than 30% loss in average transmission over that 180 degrees.

The optical Interlayer 110 can be a homogeneous material, a composite, or a heterogeneous material. The optical in 110 can be organic (polymers, plastics, etc.) or inorganic. There are countless plastics that can be used for this layer, but some specific ones include polydimethylsiloxane (PDMS), polyvinyl butyral (PVB), or polymethylmethacrylate. The optical interlayer 110 can be electrically active or insulating. In embodiments in which it is insulating, the optical interlayer 110 can be a wide bandgap semiconductor/insulator including one or more of, but not limited to SiO₂, SiOₓ, ZnO, TiO₂, and ZrO₂. In contradistinction, insulators cannot be used as an interlayer for must solar cells grown epitaxially.

The following is a list of exemplary materials that could be used in the optical interlayer 110 to achieve some or all of the effects outlined above. The list is separated into “high index” and “low index” groups. Component materials the optical interlayer 110 may include one or more of, but are not limited to: 1) High index: Si, GaAs, CdTe, Ge, CdSe, ZnSe, ZnS, CdS, SiN, (where x is ≧1.333), SiOₓ (where x≧2), TiOₓ (where x≧2), TiN, TaN, InGaP, all noble and transition metals, SiC, AlOₓ (where x≧1.5), HfO, ZnO, ZrO, and 2) low index: SiNₓ (where x is ≧1.333), SiOₓ (where x≧2), TiOₓ (where x≧2), various silicate based glasses, organic and inorganic polymers including polydimethylsiloxane (PDMS), polyvinyl butyral (PVB), polymethylmethacrylate (PMMA), ethyl vinyl acetate (EVA), low-density polyethylene, high-density polyethylene, polycarbonate.

The optical interlayer 110 can be transparent to all wavelengths over which the photovoltaic cells 22a and 22b respond, or the optical interlayer 110 can be transparent only in the wavelength range that the photovoltaic cells 22b respond. In general, the optical interlayer 110 is transmissive to wavelengths in the wavelength range of 400 nm to 1200 nm and transmits greater than 60% of light in that wavelength range. In some embodiments, the optical interlayer 110 is transmissive to wavelengths in the wavelength range of 550 nm to 1200 nm and transmits greater than 70% of light in that wavelength range and preferably greater than 95% of light in that wavelength range. In some embodiments, the optical interlayer 110 may contain structural and/or compositional characteristics that selectively reflect an average of 50% or greater of light of wavelengths of less than or equal to 600 nm. In some embodiments, the optical interlayer 110 may contain structural and/or compositional characteristics that selectively enhance transmission of by average of at least 1% of light of wavelengths of greater than 600 nm. In some embodiments, transmission is enhanced by greater than 3%. In some embodiments, transmission is enhanced by greater than 5%. In some embodiments, transmission is enhanced by greater than 7%. In some embodiments, transmission is enhanced by greater than 9%. In some embodiments, the optical interlayer 110 may contain structural end/or compositional characteristics that selectively enhance transmission of by average of up to 10% of light of wavelengths of greater than 600 nm.

For some embodiments, it may be advantageous to incorporate metals into the optical interlayer 110 to aid in electrical interconnection or light trapping and scattering. In contradistinction, incorporating metals in the interlayer into a monolithic or micromorphic multijunction solar cell would drastically change the electronic energetics of the solar cell and adversely affect its operation.

For some embodiments, it may be advantageous to incorporate optically downshifting materials into the optical interlayer 110. Such downshift materials may include downshifting nanomaterials whose wavelength-shifting properties may be matched to optimally cooperate with the primary absorption ranges of the photovoltaic materials of one of both of the networks 20a and 20b. Downshifting nanomaterials and their relationships to photovoltaic materials are discussed in detail in U.S. patent application Ser. No. 12/836,611, entitled Light Conversion Efficiency-Enhanced Solar Cell Fabricated with Downshifting Nanomaterial, which is herein incorporated by reference. In some embodiments, one, two, or all of the optical coupling layers may employ quantum dot heterostructure materials as disclosed in detail in U.S. patent application Ser. No. 12/606,908, entitled Solar Cell Constructed with Inorganic Quantum Dots and Structured Molecular Contacts, which is herein incorporated by reference.

Nanomaterials are highly suitable for use as the optical interlayer 110 and offer serious advantages over dyes. The nanomaterials are solution processible, highly controllable semiconductor nanostructures synthesized by low-cost solution based methods and can be made to have the exact optical properties desired for the optical interlayer 110. Because of their unique structure and composition, nanomaterials can be more stable than dyes.

Nanomaterials, such as semiconductor nanocrystals, are materials with at least one nano-scale dimension, are most often grown colloidally, and have been made in the form of dots, rods, tetrapods, and even more exotic structures. (See Scher, E. C.; Manna, L.; Alivisatos, A. P. Philosophical Transactions of the Royal Society of London. Series A: Mathematical, Physical and Engineering Sciences 2003, 361, 241 and Manna, L.; Milliron, D. J.; Meisel, A.; Scher, E. C.; Alivisatos, A. P. Nat Mater 2003, 2, 382-385.) Their sizes generally range from 3 nm to 500 nm. Due to the quantum size effects which arise from a material having dimensions on the order their electron's bohr radius, the bandgap of the material can also be tuned (See Alivisalos, A. P. J. Phys. Chem. 1996, 100, 13226-13239 and Bawendi, M. G.: Steigerwald, M.; Brus, L. E. Annual Review of Physical Chemistry 1990, 41, 477-496.) In addition to facilitating tunability of the bandgap for absorption and emission, the nanomaterials have near perfect crystallinity, allowing them to attain extremely high photoluminescence (See Talapin, D. V.; Nelson, J. H. Shevchenko, E. V. Aloni, S.; Sadtler, B.; Alivisatos, A. P. Nano Lett 2.007, 7, 2951-2959 and Xie, Battaglia, Peng, X J. Am. Chem, Soc. 2007, 129, 15432-15433.)

In some embodiments, the optical interlayer 110 includes nanomaterials, particularly nanocrystals such as quantum dot heterostructures (QDHs), encapsulated discretely by secondary materials through a micelle approach. Quantum dot heterostructures are a for of nanomaterial engineered for a specific application, such as downshifting. FIG. 14 is an exemplary simplified enlarged drawing of an encapsulated quantum dot heterostructure 150. With reference to FIG. 14, an encapsulated quantum dot heterostructure 150 includes a quantum dot heterostructure 160 haying a core 162 surrounded by one or more shells 164. The shell 164 is further encapsulated by an encapsulating material 166.

By discretely encapsulating each quantum dot heterostructure 160 individually, it is possible to homogeneously disperse the quantum dot heterostructures 160 in a matrix media of the optical interlayer 110, as well as protect the surface of the quantum dot heterostructures 160 from the external environment. Therefore, the use of the encapsulating materials 166 greatly helps to both passivate surface defects of the quantum of heterostructures and isolate the individual quantum dot heterostructures 160 for better dispersion. Thus, the encapsulating materials 166 minimize the interaction among the quantum dot heterostructures 160, improving the stability as well as the homogeneity in a matrix media.

The outer encapsulating materials 166 can be grown on individual quantum dot heterostructures 160 non-epitaxially. Micelles are formed using a pair of polar and non-polar solvents in the presence of a compatible surfactant. The surface polarity of a quantum dot heterostructure 160 can be modified so that only a single quantum dot heterostructure 160 will reside in an individual micelle. By adding additional precursors, an inorganic, or organic polymeric casing of encapsulating material 166 can be selectively grown on the quantum dot heterostructure 160 inside of the micelle, which acts as a spherical template. (See Selvan, S. T.; Tan, T. T.; Ying, J. Y. Adv. Mater., 2005, 17, 1620-1625; Zhelev, Z.; Ohba, H.; Bakalova, R. J. Am. Chem. Soc., 2006, 128, 6324-6325; and Qian, L.; Bera, D.; Tseng, T.-K, Holloway, P. H. Appl. Phys. Lett., 2009, 94, 073112.)

Thus, by tuning the synthetic conditions, a single nanocrystal 160 can be discretely incorporated in a silica sphere as shown in FIG. 14. Throughout the encapsulation process, the nanocrystal surfaces are well passivated to avoid any aggregation problems. Additionally, this passivation endows the quantum dot heterostructures 160 with photoluminescence quantum yields of and near unity. For the quantum dot heterostructures 160, the matrix compatibility can be dependent on the surface of the encapsulating sphere, not the nanocrystal 160. Since the surface of the encapsulating material 166 is spatially removed from the nanocrystal surface, alterations to the exterior of the encapsulating material 166 do not adversely affect the electronic or optical properties of the nanocrystal.

Semiconductor nanocrystals, such as cadmium selenide or indium phosphide, have widely been studied for control over both their composition and shape. (See Scher, E. C.; Manna, Alivisatos, A. P. Philosophical Transactions of The Royal Society of London, Series A: Mathematical, Physical and Engineering Sciences 2003, 361, 241 and Talapin, D. V.; Rogach, A. L.; Shevchenko, E. V.: Kornowski, A.; Haase, M. Weller, H. J. Am. Chem. Soc 2002, 124, 5782-5790.)

Thus, in addition to spherically-shaped nanostructures, various non-spherical nanostructures have been demonstrated including, but not limited to, nanorods, nanotetrapods, and nanosheets. Non-spherical semiconductor quantum dot heterostructures 160 have different unique physical and electronic properties from those of spherical semiconductor nanocrystals. These properties can be employed advantageously in the optical interlayer 110.

In some embodiments, the optical interlayer 110 may include individually encapsulated quantum dot heterostructures 160 employing one type of core material, one type (composition) of shell material, and one shape of shell material. In some embodiments, the optical interlayer 110 may include individually encapsulated quantum dot heterostructures employing two or more varieties of individually encapsulated quantum dot heterostructures, such as a first type of individually encapsulated quantum dot heterostructure employing a first type of core material, a first type of shell material, and to first shape of shell material and a second type of individually encapsulated quantum dot heterostructure employing the first type of core material, the first type of shell material, and at least one or more different shapes of shell material, such as rods and tetrapods.

In some embodiments, the second type of individually encapsulated quantum dot heterostructure employs a first type of core material, at least one or more different types of shell material, such as ZnS or CdS, and the first of at least one or more different shapes of shell materials. In such embodiments, each shell material may be associated with a specific shape, or each shell material may be formed with a plurality of shapes. In some embodiments, the second type individually encapsulated quantum dot heterostructures employs at least one or more different types of core materials, the first or one or more different types of shell materials, and the first or one or more different types of shell shapes. In such embodiments, each core material may be associated with specific shell materials and/or shapes, or each core material may be associated with one or more shell materials and/or shapes.

In some examples, the optical interlayer 110 includes quantum dot heterostructures having CdSe dot cores 162 with a rod-shaped CdS shells 164, encapsulated in a silica encapsulating material 166. This quantum dot material exhibits maximum absorption at wavelengths shorter than 500 nm and maximum emission at wavelengths between 550-708 nm.

In some embodiments, the quantum dot heterostructures can include one or more of the following inorganic compounds and/or any combination of alloys between them: CdSe, CdS, CdTe, ZnSe, ZnS, ZnTe, CuS₂, CuSe₂, In₂S₂, In₂Se₂, CuGaSe₂, CuGaS₂, CuInS₂, CuInSe₂, PbSe, PbS, SiO₂, TiO₂, ZnO, ZrO. These materials can be arranged in cores 62, core-shells, and core-shell-shells with or without organic ligands, such as phosphoric acids, carboxylic acids, or amines.

In some examples, quantum of heterostructures including CdSe, CdSe/ZnS, CdSe/CdS, or CdTe have provided very high luminescence, Quantum dot heterostructures based on the II-VI chalcogenides are very well understood as high efficiency emitters. In solution, the quantum dot heterostructure particles have quantum efficiencies as high as 95%. The quantum dot heterostructure materials may be distributed in matrices of polydimethylsiloxane, polyvinyibutyral, or ethylvinylacetate, for example, and may be incorporated into encapsulating material.

The optical interlayer 110 can provide tunable light absorption and re-emission. The optical interlayer 110 can contain high photoluminescence quantum yield (PLOY) light emitters, which can absorb light of a certain wavelength and re-emit the absorbed photon at a different wavelength. Similar to the downshifter concept, this light emission component ensures capture and collection of short wavelength light that was able to escape the photovoltaic material of the top network 20a and ensure highly efficient conversion of those remaining photons by the photovoltaic material of the lower network 20b.

With reference again to FIG. 9, in one embodiment, the network 20b includes photovoltaic cells 22b that employ a wafer-based mc-Si photovoltaic material, the network 20a includes photovoltaic cells 22a that employ a thin-film a-Si photovoltaic material, and the optical interlayer 110 employs ethylvinyl acetate.

In one embodiment, the photovoltaic material of the lower bandgap network 20b has an optimized absorption range of wavelengths from 600 nm to about 1200 nm and a transmittance of greater than 50% of wavelengths longer than about 1200 nm when used as the middle network in a triple stack configuration. The photovoltaic material of the higher bandgap network 20a has an optimized absorption range of wavelengths from 300 nm to 750 nm, transmits greater than 80% of wavelengths greater than 750 nm, and reflects less than 15% of wavelengths longer than 750 nm. The front contact 56 is transmissive to greater than or equal to 90% of the light in the wavelength range of 300 nm to 900 nm, is transmissive to greater than or equal to 80% of the light in the wavelength range of 900 nm to 1200 nm, and exhibits a sheet resistivity of less than 100 Ohms/square. The bottom contact 70 is transmissive to greater than or equal to 80% of the light in the wavelength range of 700 nm to 1200 nm and exhibits a sheet resistivity of less than 200 Ohms/square. The optical interlayer 110 is transmissive to wavelengths in the wavelength range of 550 nm to 1200 nm and transmits greater than 70%, and preferably greater than 95%, of light in that wavelength range.

In one optional, additive or alternative embodiment, the photovoltaic cells 22b employ mc-Si photovoltaic material and are adapted for use in a bottom network 20b, optionally or additionally a lower bandgap network 20b. Instead of being subject to tradeoffs for maximizing the spectral response across a broad range of wavelengths in the solar spectrum (from about 300 to 1150 nm), the mc-Si-based photovoltaic cells 22b can utilize tradeoffs to optimize for reflectance of short wavelengths (such as less than 700 nm) and for absorption in a narrower spectral window (such as greater than 650 nm) for improved use in a lower bandgap network 20b. In particular, many changes can be made to the cell structure and fabrication recipe that result in photovoltaic cells 22b that not only perform better in bottom network 20b of a tandem module, but can also improve the performance of the overlying photovoltaic cells 22a.

In one optional, additive or alternative embodiment, the mc-Si photovoltaic tell 22b is markedly different from a standard single-junction mc-Si solar cell in that the short wavelength spectral response of the mc-Si photovoltaic cell 22b is severely hampered by both highly reflective passivation layers and a highly doped emitter. However, this decrease in spectral response is compensated by the high spectral response of the overlying photovoltaic cell 22a.

Moreover, design rules can be formulated for improvements in the photovoltaic cells 22b of a network 20b in a mechanically stacked tandem solar panel 24. These process changes also allow more freedom for optimization of cell voltage and fill factor (FF). (Fill factor is the ratio (percent) of the actual maximum obtainable power to the theoretical power.) Independent optimization of the spectral response, fill factor, and voltage of an mc-Si photovoltaic cell 22b can yield an overall more efficient solar panel 24 relative to a tandem device utilizing an mc-Si solar cell optimized for single-junction operation. These modifications of the MC-Si photovoltaic cell 22b and the network 20b can be accomplished with off-the-shelf, in line solar cell fabrication equipment.

In particular, at least one of four fabrication modifications can be implemented to optimize the mc-Si photovoltaic cell 22b for use in a bottom network 20b in a tandem solar panel 24 (and, therefore, optionally sub-optimize the mc-Si photovoltaic cell 22b for use in stand-alone operation).

In an optional fabrication modification, the diffused, phosphorus-doped emitter layer 200 of the mc-Si photovoltaic cell 22b is made to have lower sheet resistance than that of traditional single-junction mc-Si solar cells. Diffusing a thicker and/or more conductive emitter layer 200 can provide better gettering of impurities by the phosphorus diffusant to improve material quality, can lower series resistance, and can increase manufacturing yields due to less fire-through of the contact material. A highly conductive emitter layer 200 is selected against for solar cells used in single-junction applications because the optical properties of such a highly conductive emitter layer 200 would adversely affect the blue spectral response of the soar cell.

In an optional or additional fabrication modification, the grid pattern 38 of the front contact 33 of the mc-Si photovoltaic cells 22b is designed such that its gridlines 238 are farther apart. Such redesigned front grid pattern 38 shades the mc-Si photovoltaic cells 22b less. A front contact 33 with widely spaced gridlines 238 is undesirable in a single-junction solar cell because series resistance and, in turn, diode fill factor are adversely affected. Because, as previously described, the phosphorus doped n+ emitter layer 200 on the front surface of the photovoltaic cell 22b is thicker and/or more heavily doped than traditional single-junction solar cells, the front surface/emitter layer 200 therefore contributes less series resistance and fill factor loss. As such, the front electrode grid pattern 38 for mc-Si photovoltaic cells 22b can be designed to have greater spacing 240 between the gridlines 238, which leads to less shading by the electrode grid pattern 38 and greater overall short circuit current generated by the underlying photovoltaic material 22b. Thus, a sub-optimum thickness of the emitter layer 200 (especially with respect to single-junction solar cells) can be purposefully employed to facilitate wide spacing of the gridlines 238 to decrease the fractional shading by the top grid contact 33.

In an optional or additional fabrication modification, the thickness of the anti-reflective coating is optimized for a reflectance minimum (the wavelength reflecting the least amount of light) in the 750-1100 nm wavelength range. In some implementations, the anti-reflective coating could employ a two-layer anti-reflective coating of silicon nitride and silicon oxide.

In an optional or additional fabrication modification, the front surface texture of photovoltaic cells 22b can be changed such that their surface is highly reflective to shorter wavelengths to act as an efficient back reflector for the overlying photovoltaic cells 22a to increase their current. For example, in one preferred implementation, a modified mc-Si photovoltaic cell 22b is employed in a bottom network 20b and is coupled with an amorphous thin silicon (a-Si) photovoltaic cell 22a in a top network 20a in a tandem solar panel 24. The modified mc-Si photovoltaic cell 22b reflects short wavelength light (300-650 nm) back into the active area of the a-Si photovoltaic cell 22a to improve light absorption by the thin e. Si photovoltaic cell 22a and thereby increase its current generation.

The optional, additional or alternative fabrication modifications are now described in detail with reference to a photovoltaic cell 22n containing mc-Si photovoltaic material. However, the general concepts of these fabrication modifications can be applied to the other mentioned photovoltaic materials for use in the bottom photovoltaic cells 22b in the networks 20b.

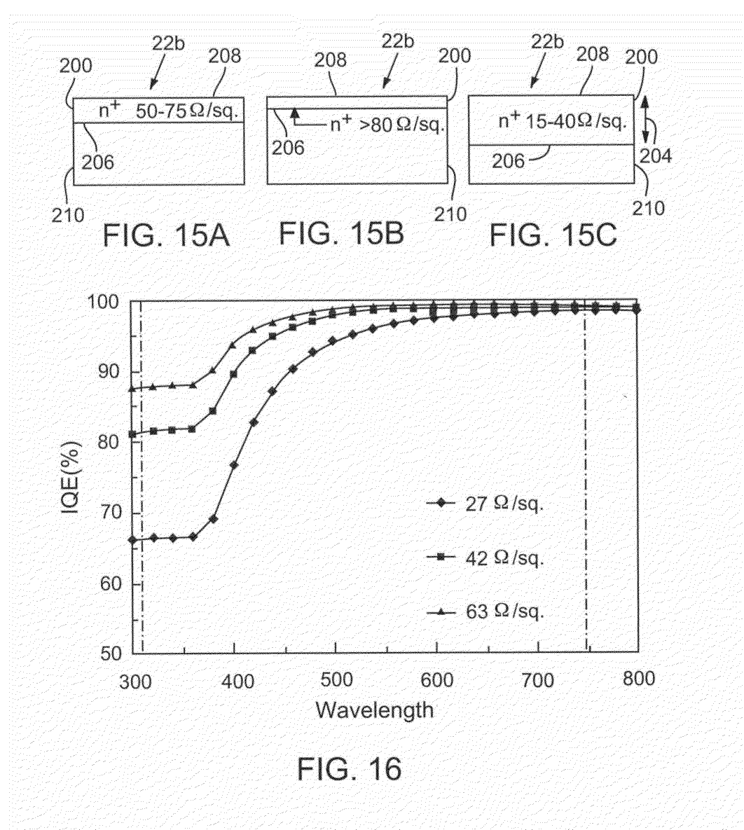

FIGS. 15A, 15B, and 15C are schematic cross-sectional views of the top surface of mc-Si cells, respectively showing the emitter thickness 204 and sheet resistance of respective standard solar cells for single-junction applications, future solar cells for single-junction applications, and photovoltaic cells 22b for use in a bottom network 20b of a tandem solar pane 24.

In most commercially available single-junction mc-Si solar cells based on a p-type wafer, the front surface of the solar cell is doped with phosphorus through a high temperature diffusion process to create a heavily doped n-type emitter layer. With reference to FIG. 15A, the sheet resistance of the emitter layer 200 is of order 45-75 Ohms/square and the depth of its p-n junction 206 is roughly 100 nm below the top surface 208 of the silicon of the photovoltaic material 22b. The high free charge-carrier concentration in this layer reduces spectral response of the solar cell in the wavelength range of 300-500 nm through a process called Auger recombination.

FIG. 15B shows an emitter layer 200 of a mc-Si solar cell that is targeted for mass production within about the next three years. Because of the adverse effect on the spectral response, most companies that manufacture silicon solar cells are trying to decrease the thickness 204, and therefore increase the sheet resistance, of this emitter layer to minimize its detrimental effect on the short wavelength response. These cells have emitter sheet resistances of order 80 Ωsq or greater. Other new designs for mc-Si solar cells for use in single-junction applications may seek to develop technologies for selective emitter placement, for creating somewhat thia, highly doped emitter regions only directly beneath the gridlines 238 of the front grid contact 31 (See Wenham, S. R. and Green, M. A., “Self aligning method for forming a selective emitter and metallization in a solar cell,” U.S. Pat. No. 6,429,037.)

Because the photovoltaic cells 22b are designed to be used in a bottom network 30b of a tandem solar panel 24, the emitter layer 200 can be much thicker, and its sheet resistance can be roughly 15-40 Ω/sq, as shown in FIG. 15C. This increased emitter thickness 204 can be made to occupy the entire surface area of the photovoltaic material of the photovoltaic cells 22b to facilitate ease of manufacturing. Alternatively, the increased emitter thickness 204 can be made to occupy a major portion (more than half) of the surface area of the photovoltaic material of the photovoltaic cells 22b. Alternatively, the increased emitter thickness 204 can be made to occupy selected regions of surface area of the photovoltaic material of the photovoltaic cells 22b, such as directly beneath the gridlines 238 of the contact 33, or other areas that might be shaded by components of the top network 20a. Alternatively, the increased emitter thickness 204 can be made to occupy the entire surface area of the photovoltaic material of the photovoltaic cells 22b, except for regions underlying selected areas (such as gridlines 338) which can be even thicker.

Areas of thicker emitter decrease the series resistance in the photovoltaic cells 22b and result in a higher diode fill factor under illumination. Employing a thicker emitter layer 200 also improves manufacturability of the mc-Si photovoltaic cells 22b and fabrication yields at the contact firing step, because the front grid contact 33 is less likely to punch through a thicker emitter layer 200, as opposed to punching through the thin standard and future thinner emitter layers 200 for solar cells for use in single-junction applications, wherein such punching through would create a shunt pathway with the p-type wafer bulk layer 210 below the emitter layer 200.

FIG. 16 is a graph showing simulated Internal Quantum Efficiency (IQE) curves as a function of wavelength for three different emitter sheet resistances. The IQE is a measure of how efficiently a photovoltaic cell converts absorbed photons into useable power. With reference to FIG. 16, the short wavelength response between 300-500 nm is dramatically decreased when decreasing the sheet resistance of the heavily doped n-type emitter layer 200. Because IQE decreases with decreasing emitter sheet resistance, IQE generally also decreases as the emitter thickness 204 increases.

Because the mc-Si photovoltaic cells 22b are designed for use in the bottom network 20b in a tandem solar panel 24, the sunlight in the wavelength range of 300-750 nm is principally absorbed and efficiently converted by the top the photovoltaic cells 22a that may reside directly above the entire mc-Si photovoltaic ells 22b or directly above major portions of the mc-Si photovoltaic cells 22b.

The dashed lines denote the boundaries of the wavelength range that is absorbed and converted to electrical power by the top photovoltaic cells 22a. Therefore, little or no sunlight at these wavelengths reaches the bottom mc-Si photovoltaic cells 22b and the spectral response of the bottom photovoltaic cells 22b in this wavelength range is irrelevant to the spectral response of the overall tandem solar panel 24.

The decreased emitter sheet resistance can be accomplished with the same manufacturing tools as are used in conventional mc-Si solar cell fabrication. The manufacturing process can be modified to run for a longer time or at a higher temperature to diffuse the phosphorous atoms deeper into the mc-Si wafer to create the mc-Si photovoltaic cells 22b. In some additional or alternative implementations, the emitter junction 206 optionally has a depth between 250 and 600 nm (i.e., the thickness of emitter layer 200 is between 250 and 600 nm) and the emitter layer 200 optionally has a sheet resistance between 15 and 40 Ohms/square. In one preferred embodiment, the emitter junction has a depth of 600 nm, and the emitter, layer 200 has a sheet resistance 25 Ohms/square.

In some additional or alternative implementations, the emitter junction 206 optionally has a depth of greater than 150 nm, 200 nm, or 250 nm. In some additional or alternative implementations, the emitter junction 206 optionally has a depth between 250 and 800 nm, between 300 and 750 nm, or between 400 and 700 nm.

In some additional or alternative implementations, the emitter layer 200 optionally has a sheet resistance of less than 40 Ohms/square, less than 25 Ohms/square, or 15 Ohms/square. In some additional or alternative implementations, the emitter layer 200 optionally has a sheet resistance of between 10 and 40 Ohms/square or between 16 and 30 Ohms/square.

As previously discussed, decreasing the sheet resistance of the emitter layer 200 decreases the series resistance of the mc-Si photovoltaic cells 22b. With lower sheet resistance in the emitter layer 200, the distance that charge carriers must travel in the emitter layer 200 can be increased. Thus, the top metallization gridlines 238 can be spaced farther apart and the photovoltaic cells 22b can still maintain diode fill factors greater than 77%. By spacing gridlines 238 farther apart, fewer gridlines 238 are needed and the to surface 208 is therefore covered (or shaded) by less metal (See Morvillo, P. et al, Mat. Sci, and Engr. B, 159-160, p, 318 (2009).) This decrease in the surface area of the photovoltaic cells 22b that is shaded from the sun increases the short circuit current generated by the photovoltaic cells 22b.

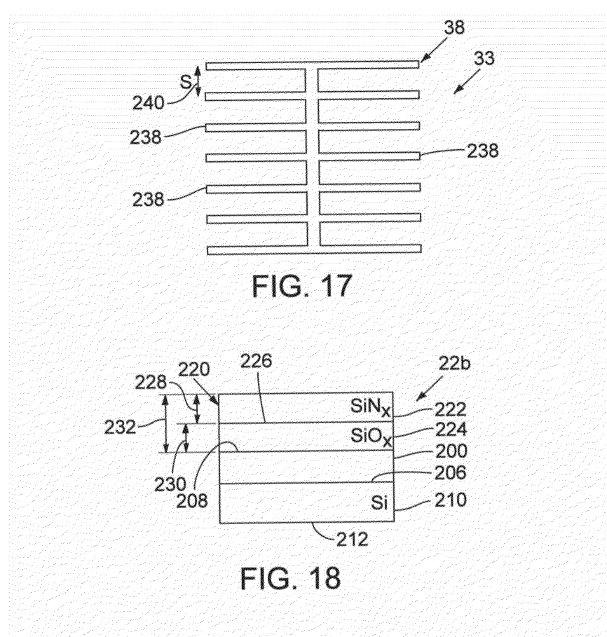

FIG. 17 is a simplified plan view of a typical top grid contact 33 for an Si photovoltaic cell 22b. The gridline pitch 240 (center-to-center spacing, s, between gridlines 238) for typical commercially available photovoltaic cells is roughly between 2 and 2.7 mm. With higher sheet resistance and selective emitter technologies, the gridline pitch 240 is actually expected to decrease within next few years for typical solar cells. However, for the photovoltaic cells 22b for use in a bottom network 20b, the gridline pitch 240 can optionally be increased to be greater than 3 mm, which can decrease the magnitude of shading of the surface 208 by at least 25%.

The modified grid pattern 38 can be made on standard manufacturing equipment, and, in the case of screen printed metallization, the modified grid pattern 38 can be fabricated by simply changing out a silk screen with an updated design in some additional, or alternative implementations, the gridline pitch 240 can optionally be greater than 4 mm or greater than 5 mm. In some additional, or alternative implementations, the gridline pitch 240 can optionally be between 3 and 8 mm, between 3 and 6 mm, or between 5 and 7 mm.

In some additional or alternative implementations, the grid pattern 38 optionally shades less than 20% of the area of the surfaces 208 of the photovoltaic cells 22b, less than 15% of the area of the surfaces 208 of the photovoltaic cells 22b, less than 10% of the area of the surfaces 208 of the photovoltaic cells 22b, less than 6% of the area of the surfaces 208 of the photovoltaic cells 22b, or less than 5% of the area of the surfaces 208 of the photovoltaic cells 22b, less than 4% of the area of the surfaces 208 of the photovoltaic cells 22b, less than 3% of the area of the surfaces 208 of the photovoltaic cells 22b, or less than 1% of the area of the surfaces 208 of the photovoltaic cells 22b, in some additional or alternative implementations, the grid pattern 38 optionally shades more than 1% of the area of the surfaces 208 of the photovoltaic cells 22b.

In some additional or alternative implementations, the number of gridlines 238 in the top metallization pattern 38 for the photovoltaic voltaic cell 22b is optionally between 20 and 60, between 30 and 55, or between 25 and 40. In some additional or alternative implementations, the number of gridlines 238 is optionally is less than 60, less than 50, or less than 40.

The modified grid pattern 38 can optionally be used in the absence of or with the cooperation of thin layers of TCO as previously described.

As briefly discussed previously, the front surface 205 of the bottom photovoltaic cells 22b may also be modified to exhibit reflective properties for efficient back reflection into the top photovoltaic cells 22a. Standard solar cells have front surface texture and anti-reflective coating that have been designed and optimized to allow the solar cell to capably absorb a very wide range of wavelengths, roughly 300 to 1150 nm. Commonly, acidic etchants are used to create a front surface that scatters light and increases the path length that a photon travels inside the silicon active region. The standard anti-reflective coating is most often a thin layer of silicon nitride with refractive index of about 2.0 that is applied to the textured surface to create broadband anti-reflective properties with a reflectance minimum (wavelength reflecting the least amount of light) between 600-700 nm. This low reflectance over a large spectral range is reached at the expense of higher operating voltages for the overall solar cell because rough surfaces can be difficult to passivate (due to their higher density of dangling bond defects on the surface) and because silicon nitride is a poor surface passivation layer relative to some other options, such as aluminum oxide or silicon oxide. (See Kerr, M. J. et al, Journal Appl. Phys. 89, p. 3821 (2001).)

Higher operating voltages could be achieved by changing or decreasing the magnitude of the surface texture, or changing the front surface passivation scheme, both of which will decrease the density of recombination causing defects and therefore decrease the magnitude of recombination at the front surface. However, such modifications to solar cells for use in single-junction applications would result in both higher reflection and lower spectral response at short wavelengths.

However, with respect to the mc-Si photovoltaic cells 22b for use in bottom networks 20b, the photons at the shorter wavelengths, such as from 300 to roughly 750 nm, are being converted by the top photovoltaic cells 22a of the top network 20a. Because the bottom mc-Si photovoltaic, cells 22b are no longer responsible for efficient conversion of the shorter light wavelengths, the reflectance, light trapping, and surface passivation properties of the bottom mc-Si photovoltaic cells 22b can be more finely tuned to improve operating voltages and spectral response at longer wavelengths.

In some optional, additive, or alternative embodiments the chemical solution used to texture the wafer surface 108 can be modified. Solar cell wafers are typically exposed to a mixture of nitric acid, hydrofluoric acid, acetic acid, and water to texture the wafer surface 108. The mixture is often mostly rich in nitric acid (greater than 35% by volume) and creates a pitted surface on the wafer. However, decreasing the nitric acid concentration to a level less than 30% or changing this etch to an alkaline-based etch can increase the surface reflectivity at shorter wavelengths and produce a smoother surface 208. The smoother front and back surfaces 208 and 212 are more easily passivated, and the higher duality passivation causes lower surface defect recombination of charge carriers and thereby facilitates higher open circuit voltage. A smoother back surface 212, exhibiting lower surface recombination, can also improve the spectral response at long wavelengths. An exemplary etchant composition is 25%:25%:50% by volume of HF(49%):HNO₃(65%):H₂O.

In some optional, additive, or alternative implementations, the root-mean-square (RMS) roughness of at least one of the surface 208 or 210 of the wafer after texturing is less than 2000 nm. In some optional, additive, or alternative implementations, the RMS roughness of at least one of the surfaces 208 or 210 of the wafer after texturing is not less than 100 nm. In some optional, additive, or alternative implementations, the RMS roughness of at least one of the surfaces 208 or 210 of the wafer after texturing is within the range of 500 nm 1200 nm.

In some optional, additive, or alternative embodiments, the front surface silicon nitride of a conventional solar cell can be replaced with a to nitride (SiNₓ)/silicon oxide (SiOₓ) stack or configuration 220 as passivation layers 222 and 224 for the front surface 208 and/or back surface (reflector) 212. FIG. 18 is schematic cross-sectional view of such two-layer configuration 220 on the top surface 208 of an Si-based photovoltaic cell 22b for a network 20b. Such two-layer configuration 220 provides a means to improve passivation of the front surface 208 because the silicon oxide layer 224 can create an interface with silicon that has fewer defects, in typical solar cells for single unction applications, silicon oxide layer 224 is sufficiently thin to avoid disrupting the anti-reflective properties of the silicon nitride layer 222 end degrading the broadband spectral response of the solar cell. For such architectures, the thickness of that silicon oxide layer is typically no more than about 20 nm. However, when used for photovoltaic cells 22b, the SiOₓ layer 224 can be made much thicker, though the upper bound of the thickness of this layer may be limited by its reflective properties in the stack. In this architecture, the thickness of the SiOₓ layers is preferably in the range of 45-55 nm but optionally in any of the ranges subsequently discussed. The extra thickness improves the passivation properties the layer's front surface 225 as annealing and densification of the oxide occur as it is grow ng.

Once the SiNₓ layer 222 is applied, the combination of the two films acts as an excellent anti-reflective coating for longer wavelengths. The two-layer configuration 220 also acts as an excellent reflector of short wavelengths. This configuration 220 can thus reflect short wavelength photons back into the top photovoltaic cells 20a if the photons were not absorbed in the first pass through the top photovoltaic cells 20a. This configuration 220 is especially useful for potential top cell photovoltaic material systems that utilize thinner absorber layers in order to maximize current collection and open circuit voltage. Moreover, this configuration 220 allows the top cell photovoltaic material to be thinned but still capture a large fraction of the incident light. For example a thin a-Si top cell (<200 nm) layer could be made to capture more than 50% of wavelength roughly 700 nm, whereas a typical semi-transparent a-Si layer of that thickness would typically capture less than 50% at this wavelength.

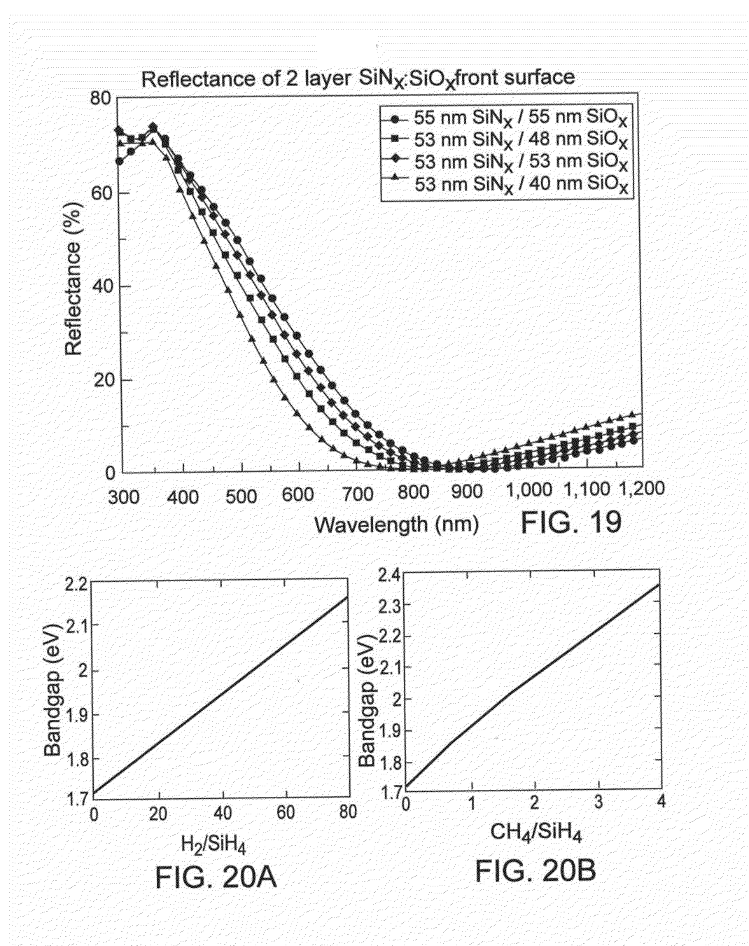

FIG. 19 is a graph showing simulated reflectance plots for different thickness combinations of SiN, and SiOₓ. In exemplary two-layer configurations 220, a reflectance minimum can be achieved at wavelengths shorter than 700 nm, while the reflectance at short wavelengths can be greatly increased relative to a single layer SiNₓ anti-reflective coating on a textured Si wafer.

In some additive or alternative implementations, an exemplary SiNₓ thickness 228 is optionally greater than 25 nm, greater than 40 nm, or greater than 50 nm. In some additive or alternative implementations, the SiNₓ thickness 228 is optionally between 25 and 80 nm, 30 and 70 nm, or 40 and 60 nm. In some additive or alternative implementations, the SiNₓ composition optionally includes a value for x, wherein 1<x<1.33. In some additive or alternative implementations, the SiN composition has a refractive index n, wherein 2<n<2.08.

In some additive or alternative implementations, an exemplary SiOₓ thickness 230 is optionally greater than 40 nm, greater than 50 nm, or greater than 60 nm. In some additive or alternative implementations, the SiOₓ thickness 230 is optionally between 25 and 125 nm, 40 and 110 nm. 48 and 100 nm, or 55 and 90 nm. In some additive or alternative implementations, the SiOₓ composition optionally includes a value for x, wherein 1.4<x<1.99. In some additive or alternative implementations, the SiOₓ composition has a refractive index n, wherein 1.47<n<1.55.

In some additive or alternative implementations, the SiN, thickness 228 and the SiOₓ thickness 230 have an optional minimum configuration thickness 232 of 70 nm, 90 nm, or 120 nm. In some additive or alternative implementations, the SiN, thickness 228 and the SiOₓ thickness 230 have an optional maximum configuration 232 thickness of 40 nm, 160 nm, or 180 nm.

In some additive of alternative implementations, the minimum reflectance wavelength is optionally greater than 700 nm, 775 nm, or 825 nm. In some additive or alternative implementations, the minimum reflectance wavelength is optionally shorter than 1200 nm or 1100 nm. In some additive or alternative implementations, the minimum reflectance wavelength is optionally between 700 and 1200 nm, 750 and 1100 nm, or 808 and 1000 nm.

In some additive or alternative implementations, the SiN thickness is optionally between 40 and 60 nm, the SiOₓ thickness is optionally between 48 and 100 nm, and the minimum reflectance wavelength of the two-layer stack on top of the silicon cell is optionally between 750 and 1100 nm (˜850 nm is preferred).

With reference to FIGS. 2, 4, 4A, 5A, 5B, 7A, 8, and 9, some optional, alternative, or additive embodiments of the networks 22a employ one or more photovoltaic cells 20a or a one or more strings of photovoltaic cells 20a that employ a “high-gap” or “adapted-gap” a-Si or a-SiC p-i-n photovoltaic material. (The high gap a-Si may also be referred to as “protosilicon” because it is in a highly amorphous state.) As previously discussed, the p-layer is a semiconductor that primarily conducts holes, and typically has a hole density of greater than 10¹⁸ cm⁻³. The n-layer is a semiconductor that primarily conducts electrons, and typically has a hole density of greater than 10¹⁸ cm⁻³. The i-layer or intrinsic layer is a semiconductor that is lightly doped or nearly pure, typically having a carrier a density less than 10¹⁶ cm⁻³, for example. The i-layer is positioned between the p-layer and the n-layer and functions as the junction 63 to collect charge carriers.

In some optional, alternative, or additive embodiments, the “high gap” a-Si photovoltaic cell 20a has at least one of the following characteristics: 1) a p-i-n architecture that can yield a stabilized open-circuit voltage between 0.91 and 1.3 V; 2) an i-layer that includes for is predominantly composed of a-Si with a bandgap above 1.75 eV derived from deposition from plasma enhanced chemical vapor deposition (PECVD) with a H₂/SiH₄ ratio above 10 in the process gas; 3) an i-layer including (or composed of) a-SiC with a bandgap above 1.75 eV grown from PECVD with a gas mixture including (or composed of) monomethyl silane, hydrogen, and silane; 4) an i-layer including a-SiC with a bandgap above 1.75 eV grown from PECVD with a gas mixture including methane, hydrogen, and silane: and 5) an i-layer that has a depth or thickness that is less than 175 nm.

In some optional, alternative, or additive embodiments, the a-Si photovoltaic cell 20a has a p-i-n architecture that can yield a stabilized open-circuit voltage between 0.91 and 1.3 V. In some of such embodiments, the stabilized open-circuit voltage is between 0.95 and 1.3 V, between 0.91 and 1.1 V, between 0.95 and 1.1 V, or between 9.97 and 1.1 V.

In some optional, alternative, or additive embodiments, the a-Si photovoltaic cell 20a has a bandgap above 1.74 eV. In some of such embodiments, the a-Si photovoltaic cell 20a has a bandgap above 1.78 eV. In some of such embodiments, the a-Si photovoltaic cell 20a has a bandgap below 3.27 eV.

In some optional, alternative, or additive embodiments, the a-Si photovoltaic cell 20a has a peak bandgap above 1.75 eV. In some of such embodiments, the a-Si photovoltaic cell 20a has a peak bandgap above 1.9 eV, 2.0 eV, or 2.1 eV. In some of such embodiments, the a-Si photovoltaic cell 20a has a peak bandgap below 3.0 eV.

In some optional, alternative, or additive embodiments, the a-Si photovoltaic cell 20a has peak absorption wavelength below 710 nm or a peak absorption below 660 nm.

In some optional, alternative, or additive embodiments, the a-Si photovoltaic cell 20a has photovoltaic material or an i-layer that is predominantly composed of a-Si derived from deposition from plasma enhanced chemical vapor deposition (PECVD) with a H₂/SiH₄ ratio above 10 in the process gas. In some of such embodiments, the photovoltaic material includes a-Si derived from plasma enhanced chemical vapor deposition (PECVD) with a H₂/SiH₄ ratio above 12 in the process as or above 15 in the process gas. In some of such embodiments, the photovoltaic material includes a-Si derived from plasma enhanced chemical vapor deposition (PECVD) with a H₂/SiH₄ ratio between 10 and 20 in the process gas or between 12 and 15 in the process gas. In some of such embodiments, the photovoltaic material consists essentially of a-Si derived from plasma enhanced chemical vapor deposition (PECVD) with a H₂/SiH₄ ratio of greater than 10 or a H₂/SiH₄ ratio of between 10 and 20 in the process gas or between 12 and 18 in the process gas.

In some optional, alternative, or additive embodiments, the photovoltaic material includes a-SiC grown from PECVD with a gas mixture including of monomethyl silane, hydrogen, and silane.

In some optional, alternative, or additive embodiments, the photovoltaic material includes a-SiC grown from PECVD with a gas mixture composed of methane, hydrogen, and silane.

In some optional, alternative, or additive embodiments, the i-layer of the photovoltaic cell 20a has a depth or thickness that is less than 175 nm. In some such embodiments, the i-layer has a depth or thickness that is less than 160 nm, less than 150 nm, or less than 140 nm. In some such embodiments, the i-layer has a depth or thickness that is between 110 and 175 nm, between 120 and 160 nm, or between 130 and 150 nm.

In some optional, alternative, or additive embodiments, these a-Si or a-SiC photovoltaic cells 20a of the top network 22a may be paired with any of the photovoltaic materials previously discussed for use in lower bandgap networks 20b or middle bandgap networks 20c. In some such embodiments, the lower photovoltaic cells 20b (or 20c) may have an active-layer bandgap below 1.7 eV, 1.6 eV, or 1.5 eV. In some such embodiments, the lower photovoltaic cells 20b (or 20c) may have an active-layer bandgap between 1.0 and 1.5 eV. In some such embodiments, the lower photovoltaic cells 20b (or 20c) may have a peak bandgap below 1.7 eV, 1.6 eV, or 1.5 eV. In some such embodiments, the lower photovoltaic cells 20b (or 20c) may have a peak bandgap between 1.0 and 1.5 eV. In some optional, alternative, or additive embodiments, mc-Si, or adapted mc-Si (as previously discussed), c-Si, CIGS, and CdTe are preferred photovoltaic materials for a bottom photovoltaic cell 20b paired with a high bandgap a-Si or a-SiC top photovoltaic cell 20a.

In some optional, alternative, or additive embodiments, the short circuit current of the high gap a-Si or a-SiC photovoltaic cell 20a of the network 22a is less than 10 mA/cm². In some such embodiments, the short circuit current of the “high gap” a-Si photovoltaic cell 20a is less than 9 mA/cm², less than 8 mA/cm², or less than 7 mA/cm². In some optional, alternative, or additive embodiments, the efficiency (DEFINE) of the high gap a-Si or a-SiC photovoltaic cell 20a is less than or equal to 8%, less than or equal to 7%, or less than or equal to 6%.

However, this decreased current or efficiency of the top high gap a-Si or a-SiC photovoltaic cell 20a has several advantages over other a-Si based tandems employing an i-layer with a standard bandgap near 1.72 eV. The top high gap a-Si or a-SiC photovoltaic cell 20a has a lower fill factor losses due to the lower short circuit currents and thus lower series resistance losses. The lower current enables the use of thinner, higher resistance, more transparent TCO contacts 56 and/or 70, as previously discussed. These thinner contacts allow more long-wavelength light to transmit to the bottom photovoltaic cell 20b, thereby improving the efficiency of the overall tandem module or hybrid panel.

The incident photons (and current) forfeited by the nature of the high gap a-Si or a-SiC photovoltaic cell 20a of the network 22a make it to the bottom photovoltaic cell 20b of the bottom network 22b. These additional photons increase the power produced (and overall efficiency) in the bottom photovoltaic cell 20b because both the open-circuit voltage and the current density of the bottom photovoltaic cell 20b increase with an increase in absorbed light.

In some optional, alternative, or additive embodiments, the efficiency of the bottom photovoltaic cell 20b paired with the high gap a-Si or a-SiC photovoltaic cell 20a is greater than the efficiency of the high gap a-Si or a-SiC photovoltaic cell 20a. In some such embodiments, the efficiency of the bottom photovoltaic cell 20b is more than 10% greater than the efficiency of the high gap a-Si or a-SiC photovoltaic cell 20a, more than 20% greater than the efficiency of the high gap a-Si or a-SiC photovoltaic cell 20a, or more than 30% greater than the efficiency of the high gap a-Si or a-SiC photovoltaic cell 20a.

In some optional, alternative, or additive embodiments, the efficiency of the bottom photovoltaic cell 20b paired with the high gap a-Si or a-SiC photovoltaic cell 20a has an efficiency greater than 9%, greater than 10%, greater than 12%.

In some optional, alternative, or additive embodiments, the high gap a-Si or a-SiC photovoltaic cells 20a of the top network 22a form tandem modules or hybrid solar panels 24 in which more than half of the total power generated by the tandem module or hybrid solar panel 24 (under standard incident radiation) comes from the bottom photovoltaic cells 20b of the bottom network 20b due to reduced current in the top photovoltaic cells 20a of the top network 22a. In some such embodiments, more than 60% of the total power is generated by the bottom photovoltaic cells 20b, or more than 66% of the total power is generated by the bottom photovoltaic cells 20b.

With reference again to FIGS. 2, 4, 4A, 5A, 5B, 7A, 8, and 9, the top a-Si or a-SiC photovoltaic cell 20a may be manufactured by standard vacuum deposition processes used for conventional a-Si cell fabrication, such as previously discussed (with optional modifications) with respect to a generic photovoltaic material for a to photovoltaic cell 20a. Also as previously discussed, the top a-Si or a-SiC photovoltaic cell 20a or network 22a can be deposited onto a large area substrate 54, and this top photovoltaic cell 20a or network 22a can be mechanically coupled to the bottom photovoltaic cell 20b or bottom network 22b.

One way to increase the bandgap of the a-Si photovoltaic material of the top photovoltaic cell 20a is to grow the a-Si film or layer in the presence of excess hydrogen. FIG. 20A is a graph showing the a-Si bandgap as a function of hydrogen concentration, (See also Koh, J. et al., “Evolutionary phase diagrams for plasma-enhanced chemical vapor deposition of silicon thin films from hydrogen-diluted silane,” Applied Physics Letters, Vol. 75 October 1999, page 2286.) With reference to FIG. 20A, the bandgap of a-Si increases with increasing hydrogen:silane ratio in the PECVD reaction gas mixture during growth of the photovoltaic material. This alteration is compatible with current mass production techniques and toolsets and poses only slight changes to recipes.

An alternative way to increase the bandgap of a-Si photovoltaic material of the top photovoltaic cell 20a is to incorporate carbon into the PECVD reaction gas mixture during growth of the photovoltaic material, in some optional, additive or alternative embodiments, the carbon can be his can be done by adding methane or monomethyl silane in the reaction gas mixture. FIG. 20B is a graph showing the a-Si bandgap as a function of methane concentration.

Thus, in some optional, alternative, or additive embodiments, the top a-Si or a-SiC photovoltaic cell 20a or network 22a is monolithically fabricated by: depositing a TCO (indium tin oxide, boron-doped zinc oxide, etc.) contact 56 on a large area substrate 54, such as a piece of solar glass (process step 52); scribing the TCO contact 56 into isolated stops (process step 58) (called P1 in industry); depositing a 10 to 20 nm boron-doped, p-type a-SiC layer by PECVD; depositing a 0 to 25 nm buffer layer of a-Si or a-SiC with a bandgap higher than the i-layer by PECVD; depositing a 25 nm i-layer of a-Si:H or a-SiC:H with a bandgap above 1.75 eV; depositing a 0 to 25 nm buffer layer of a-Si or a-SiC with a bandgap higher than the i-layer by PECVD; depositing a 10 to 20 nm phosphorous-doped, n-type a-SiC layer 62 by PECVD (process step 60); scribing the a-Si (or a-SiC) stack into strips (process step 66) (called P2 in industry); depositing a TCO (indium tin oxide, boron-doped zinc oxide, etc.) contact 70 (process step 68); scribing the TCO contact 70 such that the isolated strips from the TCO contact 56 are now series-connected photovoltaic cells 20a (process step 74) (called P3 in industry).

The substrate 54 onto which the a-Si or a-SiC photovoltaic cells 20 are deposited may serve as a protective glass cover for the entire tandem module or hybrid solar panel 24. Electrical connections between the top cell and the bottom cell are made with standard tabbing wire and bus contact materials.

In some optional, alternative, or additional embodiments, the top photovoltaic cell 20a may be monolithically interconnected in series using standard a-Si processing technologies to produce a series-connected network 22a. The bottom photovoltaic cells 20b of the bottom network 22b may be mechanically coupled to the photovoltaic cells 20a, and the bottom photovoltaic cells 20b or the bottom network 22b may have their own electrical terminals. The top photovoltaic cells 20a or the top network 22a can then be wired in series or parallel to the bottom photovoltaic cells 20b or the bottom network 22b, or the top and bottom networks 22a and 22b can be kept electrically isolated and fed to different loads or inverters.

In an optional, alternative, or additive implementation, the tandem module or hybrid panel 24 may include an adapted a-Si top photovoltaic, cell 20a mechanically coupled to (and wired in series or parallel with) an adapted mc-Si bottom photovoltaic cell 20b.

The adapted tandem modules or hybrid panels 24 employing a-Si or a-SiC photovoltaic materials adapted for use as the top photovoltaic cells 20a differ from conventional stand-alone a-Si solar cells and conventional multifunction tandems employing a conventional a-Si solar cell as a top cells at least partly because the energy bandgap of a standard i-layer of the conventional a-Si is chosen to maximize current in the solar cell (i.e., the conventional a-Si bandgap equals about 1.72 eV). This standard approach achieved good splitting of the solar spectrum in the context of the conventional wisdom of keeping the current density in each component cell is the same.

However, in the adapted tandem modules or hybrid panels 24, employing a-Si or a-SiC photovoltaic materials adapted for use as the top photovoltaic cells 20a as disclosed herein, the combination of bandgaps may be far from the theoretical optimums for individual solar cells and restricts the maximum achievable efficiency of the top photovoltaic cells 20a to a somewhat lower value in stand alone operation. (The overall current (and efficiency) attainable in the high gap a-Si or a-SC top photovoltaic cell 20a is lower than that often observed in a standard a-Si cell due to the much reduced photocurrent in the high gap a-Si or a-SiC top photovoltaic cell 20a.)

Nevertheless, in certain configurations and certain cell material combinations, the adapted tandem modules or hybrid panels 24 can achieve higher stability and efficiency in real world operation. For example a 4-terminal tandem module or hybrid panel 24 employing mc-Si, c-Si, or other photovoltaic material as the bottom photovoltaic cell 20b and a high-gap a-Si or a-SiC photovoltaic material as the top photovoltaic cell 20a can have a higher efficiency than a 4-terminal solar module having mc-Si, c-Si, or other photovoltaic material as the bottom photovoltaic cell 20b and a conventional a-Si photovoltaic material (E_{g} ˜1.72 eV) as the top photovoltaic cell 20a. The higher efficiency of the adapted tandem modules or hybrid panels 24 employing a-Si or a-SiC photovoltaic materials adapted for use as the top photovoltaic cells 20a is partly due to the fact that a-Si photovoltaic materials generally suffer from light-induced degradation, which is minimized for his gap a-Si and a-SiC photovoltaic materials disclosed herein, and also because the open circuit voltage and fill-factor are higher for the high gap photovoltaic cells 20a. Moreover, a mechanically-stacked tandem module or hybrid panel 24 based on the adapted a-Si or a-SiC photovoltaic material uses the top photovoltaic cell 20a to improve the blue response over that provided by a stand-alone bottom photovoltaic cell 20b. Furthermore, the adapted a-Si or a-SiC photovoltaic material of the tandem module or hybrid panel 24 permits more photons to pass to the bottom photovoltaic cell 20b, which more efficiently converts photons with wavelength below 500 nm into electrons. Even as the blue response of stand-alone c-Si or other stand-alone photovoltaic materials improves over time the efficacy of the tandem module or hybrid panel 24 employing the high gap photovoltaic materials as the to photovoltaic cells 20a can be maintained. Furthermore, increasing the bandgap of the photovoltaic material for the to photovoltaic cells 20a permits thinner TCO layers on the to photovoltaic cells 20a and allows more sunlight to pass to the bottom photovoltaic cells nib. The thinner i-layer of the adapted a-Si or a-SiC photovoltaic material also promotes higher voltages and fill factors and experiences lower light-induced degradation.

The raw materials and fabrication processes are significantly cheaper for the tandem modules or hybrid panels 24 employing the high gap photovoltaic materials, so the overall electricity costs (on a $/kWh basis) can be lower.

FIG. 10 is an isometric view of a portion of a triple-junction photovoltaic panel 24a with sections cut away to show the different networks and intervening layers. FIG. 11 is an isometric view of a portion of a triple-junction photovoltaic panel 24a with the different networks spaced apart to show network interconnections. With reference to FIGS. 19 and 11 the triple-junction photovoltaic panels 24a additionally employ a middle or intervening network 20c of middle or intervening photovoltaic cells 22c. The optical coupling layer 110 is positioned between the networks 20a and 20c, and an optical coupling layer 1106 is positioned between the networks 20c and 20b. Although the optical coupling layers 110 and 110b can have the same composition, the optical coupling layer 110 can be adapted to facilitate transmission of light within the primary absorption spectra of both of the photovoltaic cells 22c and 22b, but the optical coupling layer 110b need only be adapted to facilitate transmission of light within the primary absorption spectra of the photovoltaic cells 22b. With reference to FIG. 9, the optical coupling layers 110 and 110a can have the same composition, or the optical coupling layer 110a can be adapted to reflect light of certain wavelengths into the network 20b.

In some embodiments, the solar panel 24 may employ a triple-junction photovoltaic device (cell or panel) having a design that does not seek optimum efficiency from bandgap distribution but that may offer advantages that more than compensate for their lower value of maximum achievable efficiency.

In particular, there are many advantages for designing two of the three component cells to have substantially the same or similar primary bandgap energies, such that two of the three component cells of such “triple-junction two-bandgap tandem” photovoltaic devices have primary absorption ranges that overlap by greater than or equal to 80%. For example, two of the component cells could have primary bandgap energies that differ by less than 20% or differ by less than 340 meV. This close similarity in bandgap energies can be achieved by either light alloying or by hydrogenation of the cell materials.

Employing two of the three component cells having substantially the same bandgap energies permits at least one of the component cells to have a thickness that is less than the thickness of conventional single-junction solar cells of the same material. Thick conventional single-junction solar cells tend to exhibit low achievable voltages due to the phenomenon of field dependent carrier collection, low fill factors due to higher short circuit currents and thus higher series resistance losses, and low stabilized efficiencies due to greater light induced degradation (LID). Stabilized efficiency can be defined as the efficiency reached by a thin-film solar cell after degradation processes caused by solar irradiation have decreased the cell's conversion efficiency to a stable level. Because these degradation processes effect the lifetime and mobility of charge carriers in the cell, thinner cells have a shorter active area that the charges need to traverse to reach an electrode and be counted as current. Thinner, lower current cells can also benefit from thinner transparent electrodes. Because thick cells have high currents, they require thick, low series resistance electrodes. Thinner cells with lower currents can withstand thin electrodes with slightly higher series resistance and suffer only the same amount of loss as thick cells.

Because total photon absorption (which determines the amount of current generated) is a function of material thickness, employing a component cell having a thickness that is less than the thickness of conventional single-junction solar cells reduces the amount of current that the thinner component cell can generate to a value less than the value that a conventional single junction cell can generate. A second component cell, with a thickness that is less than or equal to the thickness of conventional single-junction solar cells and with a bandgap that substantially matches the bandgap of the overlying component cell, will have fewer photons to absorb due to absorption of the appropriate energy photons by the overlying component cell. So, the amount of current the second component cell can generate is also reduced to a value that is less than a value that a conventional single-junction cell can generate. The lower maximum current enables the use of thinner, higher resistivity, transparent conductive oxide (TCO) electrodes, such as those already discussed. These thinner contacts allow more long-wavelength light to transmit to the middle and bottom component cell, thereby improving the yield from the bottom component cell and the efficiency of the overall triple-junction photovoltaic device. Moreover, the top and middle component cells will yield a combined voltage as much as or greater than the voltage generated by the same material in a single-junction solar cell of conventional thickness. Furthermore, light induced degradation is less pronounced in thin devices as previously discussed.

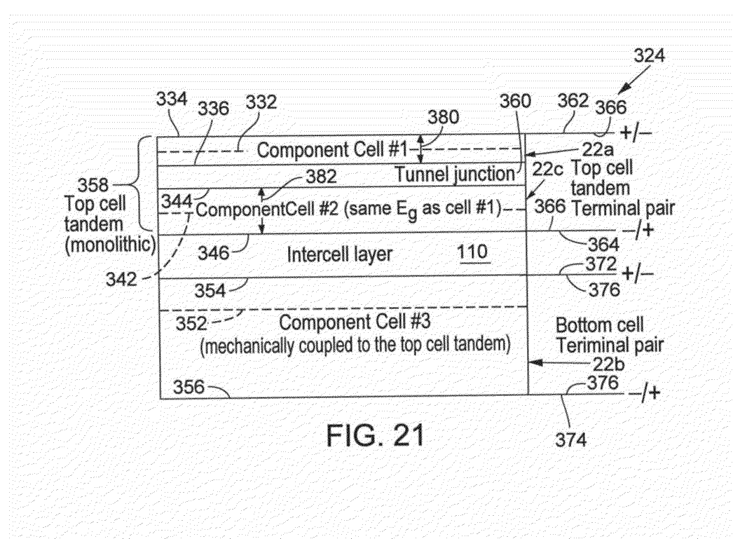

FIG. 21 is a schematic diagram of an exemplary multijunction photovoltaic device 324, such as a triple-junction two-bandgap tandem photovoltaic device, including a first component cell 22a, a second component cell 22c, and a third component cell 22b. The first component cell 22a may also be referred to as a top, upper, front, proximal, or sun-closest component cell 22. The second component cell 22c may also be referred to as a middle, center, or internal component cell 22c. The third component cell 22b may also be referred to as a bottom, lower, rear, back, distal, or earth-closest component cell 22b. These alternative designations refer to the intended relative positioning of these cells during operation after installation but may not be representative of the positioning during manufacture cc transport.

With reference to FIG. 21, the first component cell 22a includes a first photovoltaic material having a first junction 332 positioned between a first pair of spaced apart front and rear electrically conductive layers 334 and 336. The second component cell 22b includes a second photovoltaic material having a second junction 342 positioned between a second pa of spaced apart front and rear electrically conductive layers 344 and 346. The third component cell 22b includes a third photovoltaic, material having a third junction 352 positioned between a third pair of spaced apart front and rear electrodes 354 and 356. The electrically conductive layers may have any combination of properties and features previously described for the conductor layers 56 or 70. The multijunction photovoltaic device 324 also includes a tunnel junction 360 positioned between the first component cell 22a and the second component cell 22c. An intercell layer 110 is positioned between the second component cell 22c and the third component cell 22b.

The tunnel junction 350 functions as an ohmic electrical contact that acts as the series connection between the two monolithically stacked component cells 22a and 22c. A tunnel junction (also frequently referred to as a recombination junction) generally includes two highly doped semiconductors that serve as a meeting place for electrons and holes. The two highly doped semiconductors 360 typically form the electrically conductive layers 336 and 344. In some embodiments, this recombination junction can include thin, highly doped n-type and a p-type; microcrystalline silicon or amorphous SiC layers sandwiched together, between the two adjacent component cells 22a and 22c. The thickness of these layers is typically less than 50 nm each and the dopant density is greater than about 1 e^{18/}cm³.

In some embodiments, the first and second component cells 22a and 22c are stacked monolithically, i.e., both cells are deposited on the same supporting material and form a top tandem cell component 358. Like all monolithically-stacked solar cells, the first and second component cells 22a and 22c are electrically connected in series and have two electrical terminals 362 and 364 (labeled “top cell tandem terminal pair” 366) that extract the light-generated power from only the first and second component cells 22a and 22c. The top cell tandem terminals 362 and 364 can then be wired in series or parallel to terminals 372 and 374 (labeled “bottom cell tandem terminal pair” 376) of the third component cell 22b, or can be kept separate and fed to a different load than the bottom network of component cells 22b. The third component cell 22b is mechanically coupled to the top tandem cell component 368. Thus, in some embodiments, the multijunction photovoltaic device. 324 includes both monolithic and mechanically stacked cell components.

In some embodiments, the first and second component cells 22a and 22c of the multijunction photovoltaic device 324 have respective first and second photovoltaic materials that have bandgaps that substantially overlap, the absorption onset wavelengths substantially match. For example, in some embodiments, the first and second component cells 22a and 22c of such triple-junction two-bandgap tandem photovoltaic devices 324 have respective first and second photovoltaic materials that have primary absorption ranges that overlap by greater than or equal to 90%. In some embodiments, the first and second photovoltaic materials have primary absorption ranges that overlap by greater than or equal to 95%. In some embodiments, the first and second photovoltaic materials have primary absorption ranges that overlap by greater than or equal to 99%. In some embodiments, the first and second photovoltaic materials have primary absorption ranges that overlap by greater than or equal to 99.5%.

Alternatively, in some embodiments, the first and second photovoltaic materials have primary bandgap energies that differ by less than 20% or that differ by less than 340 meV, in some embodiments, the first and second photovoltaic materials have primary bandgap energies that differ by less than 10% or that differ by less than 170 meV. In some embodiments, the first and second photovoltaic materials have primary bandgap energies that differ by less than 5% or that differ by less than 85 meV, in some embodiments, the first and second photovoltaic materials have primary bandgap energies that differ by less than 1% or that differ by less than 17 meV, in some embodiments, the first and second photovoltaic materials have primary bandgap energies that differ by less than 0.5% or that differ by less than 8.5 meV.

In some examples, the first and second photovoltaic materials have primary bandgap energies within the range of about 1.6-2.0 eV. In some examples, the first and second photovoltaic materials have primary bandgap energies within the range of about 1.7-1.9 eV. In some examples, one of the first or second photovoltaic materials has a primary bandgap energy of about 1.7 eV (or 730 nm) and the other of the first or second photovoltaic materials has a bandgap energy that differs by less than one or more of the percentages previously set forth.

In some embodiments, the first and second photovoltaic materials have substantially the same chemical composition. In particular, the first and second photovoltaic materials also have substantially the same degree of crystallinity (or lack thereof). In some embodiments, the chemical composition would not vary by more than 10 atomic %. In some embodiments, the photovoltaic material of the first component cell 22a may have a higher hydrogen dilution to affect its crystallinity. This compositional difference would be less than 2 atomic %. Moreover, the photovoltaic material of the first component cell 22a may be “more” amorphous than the photovoltaic material of the second component cell 22c. (These photovoltaic material films can have some fractional crystallinity that will affect their bandgap only slightly).

Plasma-enhanced chemical vapor deposition (PECVD) is typically used to fabricate the light absorbing layers (i.e., the p-type/intrinsic/n-type semiconductor material stack) of the first and second photovoltaic materials. In one embodiment, a single piece of PECVD manufacturing equipment can be used to deposit the first photovoltaic material of the component cell 22a, the tunnel junction 360, and the second photovoltaic material of the component cell 22c without breaking vacuum or exposing the elements of the top tandem cell component 358 to ambient conditions. Moreover, most or all of the layers of the top tandem cell component 358 can be formed in a single chamber in a continuous process. If the component cells 22a and 22c are made of drastically different photovoltaic materials, then separate deposition tools, optimized for those material systems, would be desired. The redundancy of toolsets facilitated by using a common material for the first and second photovoltaic materials helps save or reduce manufacturing costs, which can help drive down the cost of the resultant photovoltaic modules.

In some embodiments, the combined thickness of the first photovoltaic material of the first component cell 22a and the second photovoltaic material of the second component cell 22c is substantially the same or thicker than the thickness of a conventional simile-junction cell of the same material. In most embodiments, the first photovoltaic material has a thickness 380 that is different from a thickness 382 of the second photovoltaic material. Moreover, because the component cell 22a and the component cell 22c are wired in series and are preferably substantially current matched (and because the component cell 22a will absorb some of the light that the lower layer could have otherwise absorbed since they have substantially the same bandgap), the thickness 380 of the first photovoltaic material is less than or equal to the thickness 382 of the second photovoltaic material in most embodiments.

In some embodiments, the thickness 380 of the first photovoltaic material is less than or equal to about 150 nm, and the thickness 382 of the second photovoltaic material is less than or equal to about 350 nm. In some embodiments, the thickness 380 is in the range of 30-150 nm. In some embodiments, the thickness 380 is less than about 100 nm. In some embodiments, the thickness 382 is in the range of 100-350 nm. In some embodiments, the thickness 382 is less than about 300 nm. In some embodiments, the thickness 382 is less than about 200 nm. These ranges are general, but apply particularly to a-Si. These ranges also apply well to InGaP. Skilled persons will appreciate that different thickness ranges and different maximum thickness limits may be appropriate for different compositions of the first and second photovoltaic materials.

In some embodiments, the first and second component cells 22a and 22c have maximum achievable open circuit voltages that substantially match. In particular, the currents generated by the component cell 22a and the component cell 22c match to within 15%. In some embodiments, the currents generated by the component cells 22e and 22c match to within 10% of each other. In some embodiments, the currents generated by the photovoltaic dells component cells 22a and 22c match to within 5% of each other. In some embodiments, the currents generated by the component cells 22a and 22c match to within 1% of each other.

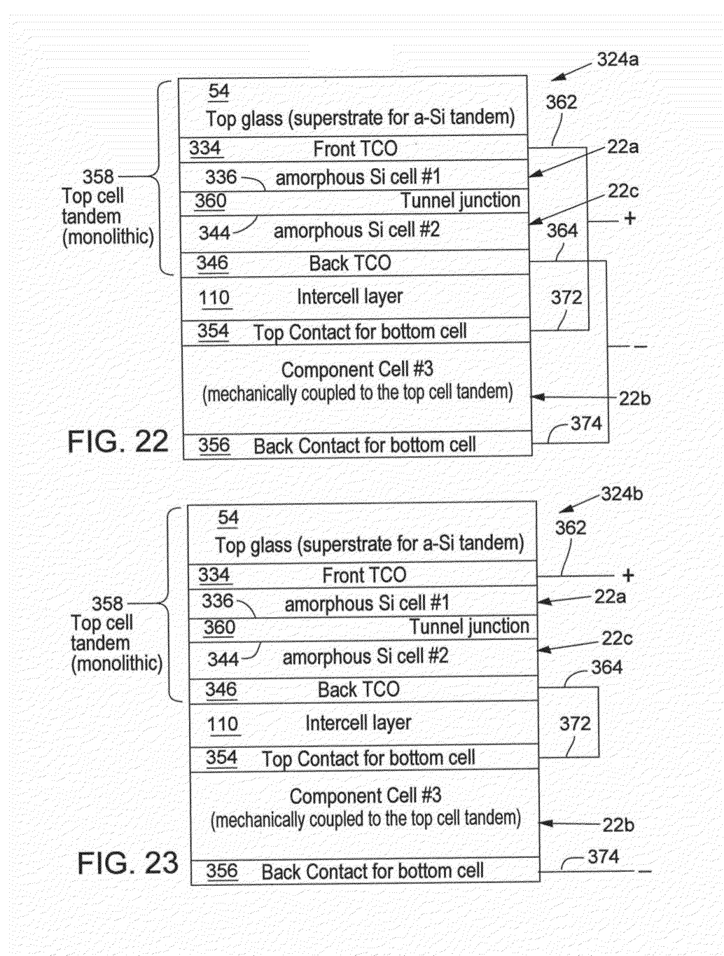

FIG. 22 is a schematic diagram of an embodiment of a triple-junction two-bandgap tandem photovoltaic device 324a with the top tandem well component 358 electrically wired in parallel with the bottom component cell 22b, and FIG. 23 is a schematic diagram of an embodiment of the a triple-junction two-bandgap tandem photovoltaic device 324b with the top tandem cell component 358 electrically wired in series with the bottom component cell 22b. With reference to FIGS. 22 and 23 some embodiments employ a top tandem cell component 58 that includes monolithically stacked component cells 22a and 22c in which the respective first and second photovoltaic materials include a-Si. The top tandem cell component 358 is mechanically coupled to a bottom component cell 22b in which the third photovoltaic material of the bottom component cell 22b includes mc-Si or c-Si. One such an embodiment may be referred to as an triple-junction two bandgap tandem photovoltaic device 324a or 324b (generically triple-junction two bandgap photovoltaic device 20). Another such an embodiment may be referred to as an a-Si/a-Si/c-Si triple-junction two bandgap tandem photovoltaic device 324a or 324b.

The a-Si top tandem cell component 358 can be manufactured by conventional vacuum deposition processes used for a-Si cell fabrication. In particular, the components of the a-Si top tandem cell component may be layered onto a lame area substrate 54, such as piece of solar glass. This “top glass” may serve as a protective glass cover for an entire solar panel of triple-junction two-bandgap photovoltaic devices 324. Electrical connections between the tandem cell component 358 and the bottom component cell 22b can be made with conventional tabbing wire and bus contact materials.

In some embodiments, the first and second photovoltaic materials have bandgap energies within a range of about 1.6-2.0 eV as previously discussed, in some embodiments, the bottom component cell 22b has a bandgap energy within the energy range of 1.4 to 0.85 eV. In some embodiments, the bottom component cell 22b has a bandgap energy within the energy range of 1.2 to 0.95 eV. In some embodiments, the bottom component cell 22b has a bandgap energy of about 1.1 eV. The triple-junction two-bandgap photovoltaic device 324 would perform such that, if the external quantum efficiency spectrum of each component cell were measured individually, the top component cell 22a would respond to the shorter wavelengths (range of 350-500), the middle component cell 22c would respond to slightly more red wavelengths (500-700 nm), and the bottom component cell 22b would respond to the near IR wavelengths (700-1100 nm).

Even though a triple-junction two-bandgap photovoltaic device 324 will have a lower theoretical maximum efficiency than a conventional three-junction three-bandgap device, in certain configurations and certain cell material combinations, the triple-junction two-bandgap tandem photovoltaic device 324 can achieve higher efficiencies in real world operation. For example, a four-terminal triple-junction two-bandgap tandem photovoltaic device 324 employing c-Si as the bottom component cell 22b pared with a tandem cell component 358 employing component cells 22a and 22c with substantially the same bandgaps can have a higher efficiency than a four-terminal three-junction three-bandgap device employing c-Si as photovoltaic material for the bottom cell and a-Si/a-SiGe for the photovoltaic materials of the top cells.

As another example, a triple-junction two-bandgap tandem photovoltaic device 324 employing c-Si as the third photovoltaic material of the bottom component cell 22b pared with a tandem cell component 358 employing component cells 22a and 22c that include a-Si as the first and second photovoltaic materials can enable efficiencies in excess of 20% in real world operation. These triple-junction two-bandgap tandem photovoltaic devices 324 will perform better than conventional two-junction a-Si/roc-Si counterparts. These triple-junction two-bandgap tandem photovoltaic devices 324 also present substantial improvements over conventional a-micromorph technology, which have reached stable efficiencies of only about 11%.

By converting a conventional single-junction a-Si cell into two-junction same bandgap tandem device within the larger a-Si/c-Si a-Si/mc-Si multijunction tandem architecture, the triple-junction two-bandgap tandem photovoltaic device 324 circumvents a number of limitations associated with amorphous silicon. These limitations include phenomena such as light-induced degradation and field dependent carrier collection, which decrease overall cell (and thus tandem cell) efficiency of conventional multijunction devices as previously discussed. These conventional limitations are common for many thin-film materials, so a triple-junction two-bandgap tandem photovoltaic device 324 as disclosed herein can alternatively employ numerous thin-film materials for the first and second photovoltaic materials. In some embodiments, the first and second photovoltaic materials include one or more of: CdSe, InₓGa₁₋ₓP, InₓGa₁₋ₓN, amorphous Si, amorphous Si:Ge, CuInₓGa₁₋ₓSe₂S_{2-y}, amorphous SiC, CuInGaSe₂, CuGaSe_{y}S_{(2-y)} where y is between 1 and 2, CuInₓGa₍₁₋ₓ₎S₂ where x is between 0.3 and 0.9, and CdTe. These CuGaSe_{y}S_{(2-y)} and CuInₓGa₍₁₋ₓ₎S₂ photovoltaic materials may have a bandgap between 1.5 and 2.0 eV.

In some embodiments, some variants of these materials may alternatively be used as the third lower bandgap photovoltaic material of the bottom component cell 22b. For example, Cu(InₓGa₁₋ₓ)Se_{y}S_{2-y} can have a variety of bandgaps. Cu(InₓGa₁₋ₓ)Se_{y}S_{2-y} can be produced with a suitable bandgap for the first and second photovoltaic materials with some values of x and y, and other values can be used to produce Cu(InₓGa₁₋ₓ)Se_{y}S_{2-y} with a suitable bandgap for the third photovoltaic material for the bottom component cell 22b. For example, Cu(InₓGa₁₋ₓ)Se_{y}S_{2-y}, having a bandgap of 0.95-1.2 eV, may be used in the bottom component cell 26, where the first and second photovoltaic materials have a higher bandgap.

In some embodiments, the lower bandgap photovoltaic material of the bottom component cell 22b includes one or more of c-Si, Cu(InₓGa₁₋ₓ)Se_{y}S_{2-y}, CuInₓGa(1-x)Se₂ where x is between 0.9 and 1, and CuInSe_{y}S_{(2-y)} where y is between 1.9 and 2. These CuInₓGa(1-x)Se₂ and CuInSe_{y}S_{(2-y)} materials have a bandgap between 1.0 and 1.2 eV.

In some embodiments, a triple-junction two-bandgap tandem photovoltaic device 324 employs a-Si for the first and second photovoltaic materials and CuInSe₇ for the third photovoltaic material of the bottom component cell 22b. Any combination of any of the higher bandgap materials with any of the lower bandgap materials is possible.

Because a conventional single-junction cell, such as an a-Si cell, is converted into a tandem cell component 358, one or both of the thicknesses 380 and 382 of the first or second photovoltaic materials 30 of the component cells 22a and 22c, respectively, can facilitate the use of one or more thinner, more highly resistive, electrically conductive layers 334 and 346, such a TCO electrodes, on the component cells 22a and 22c to allow more sunlight to pass to the bottom component cell 22b. The component cells 22a and 22c of the tandem cell component 358 permit a greater than or equal number of photons to be absorbed than does a conventional single-junction a-Si cell of standard thickness; however, the component cells 22a and 22c of tandem cell component 358 permit higher voltages, higher fill factors, and lower light-induced degradation to be achieved.

Compared to conventional three-junction solar devices, the fabrication of the triple-junction two-bandgap tandem photovoltaic device 324 is much simpler and lower cost. A triple-junction two-bandgap tandem photovoltaic device 324 need not involve the use of an expensive light-blocking, semi-insulating GaAs substrate for conventional 2-junction tandem top cells. The triple-junction two-bandgap tandem photovoltaic device 324 can employ a fully transparent, glass substrate (superstrate), which is much lower cost per unit area.

The triple-junction two-bandgap tandem photovoltaic device 324 disclosed herein also improves on conventional triple-junction cells that allegedly have been demonstrated to have higher power conversion efficiencies because, in certain embodiments, the raw materials and fabrication processes are significantly cheaper for the triple-junction two-bandgap tandem photovoltaic devices 324. Therefore, lower overall electricity costs (on a $/kWh basis) are possible with the triple-unction two-bandgap tandem photovoltaic devices 324 relative to conventional multijunction solar devices

It will be obvious to those having skill in the art that many changes may be made to the details of the above-described embodiments without departing from the underlying principles of the invention. For example, skilled persons will appreciate that subject matter revealed in any sentence, paragraph, or embodiment can be combined with subject matter from some or all of the other sentences, paragraphs, or embodiments except where such combinations are mutually exclusive or inoperable. The scope of the present invention should, therefore, be determined only by the following claims.

1. A module including a cooperative network adapted for overlaying a first network of electrically connected first photovoltaic cells, the first photovoltaic cells including a first photovoltaic material having a first region of light conversion activity that is characterized at least in part by a first primary light absorption spectrum for absorbing incident photons having first wavelengths in the first primary light absorption spectrum, the first photovoltaic cells including a first pair of positive and negative electrodes associated with the first photovoltaic material and forming part of the first network, one of the first positive and negative electrodes permitting transmission of a first portion of incident photons of a majority of first wavelengths within the first primary light absorption spectrum to permit the first portion of incident photons in the first primary light absorption spectrum to reach the first photovoltaic material, the module comprising:
a second network of electrically connected second photovoltaic cells including a second photovoltaic material having a second region of light conversion activity that is characterized at least in part by a second primary light absorption spectrum for absorbing incident photons having second wavelengths in the second primary light absorption spectrum, the second photovoltaic material being different from the first photovoltaic material such that the second primary light absorption spectrum is different from the first primary light absorption spectrum and such that the first primary light absorption spectrum includes a first subset of first wavelengths absent from the second primary light absorption spectrum, the second photovoltaic material being at least partly transmissive to incident photons of a majority of the first subset of first wavelengths within the first primary light absorption spectrum;
a second pair of positive and negative electrodes associated with the second photovoltaic material and forming part of the second network, at least one of the second positive and negative electrodes permitting transmission of incident photons of a majority of the first and second wavelengths within the respective first and second primary light absorption spectra to permit incident photons of a majority of the first and second wavelengths within the respective first and second primary light absorption spectra to reach the second photovoltaic material, another of the second positive and negative electrodes permitting transmission of incident photons of a majority of the first subset of first wavelengths within the first primary light absorption spectrum such that the second network permits transmission of incident photons of the first subset of first wavelengths within the first primary light absorption spectrum to reach the first network.

2. The module of claim 1, wherein the second photovoltaic material is manufactured by a process that is spatially-isolated from the first photovoltaic cells.

3. The module of any preceding claim, wherein the second photovoltaic material is manufactured under process conditions that are damaging to the first photovoltaic cells.

4. The module of any preceding claim, wherein the second photovoltaic cells have a second surface area that is different from a first surface area of the first photovoltaic cells.

5. The module of any preceding claim, wherein the second network has a different number of second photovoltaic cells than the first network has of first photovoltaic cells.

6. The module of any preceding claim, wherein the second network having a second number of second photovoltaic cells is electrically connected in series, parallel, or a combination of both series and parallel to the first network having a different first number of first photovoltaic cells.

7. The module of any preceding claim, wherein the second network produces a second current that matches a first current produced by the first network to within 10% of the first current.

8. The module of any preceding claim, wherein the second network produces a second voltage that matches a first voltage produced by the first network to within 10% of the first voltage.

9. The module of any preceding claim, further comprising the first network of electrically connected first photovoltaic cells positioned beneath the second network of second photovoltaic cells.

10. The module of claim 9, further comprising a network interlayer between the first network of first photovoltaic cells and the second network of second photovoltaic cells, the network interlayer having a thickness greater than a wavelength corresponding to the lowest of the lower ends of the respective first and second primary absorption spectra of the first and second photovoltaic materials.

11. The module of claim 9, wherein a network interlayer between the first network of first photovoltaic cells and the second network of second photovoltaic cells has a thickness greater than 1000 nm.

12. The module of claim 9, wherein a network interlayer between the first network of first photovoltaic cells and the second network of second photovoltaic cells includes an optical structure.

13. The module of claim 12, wherein the optical structure includes at least one of a layer of light-scattering or light-emitting particles embedded in a matrix, an optical grating, a multilayer optical coating, and photonic crystals.

14. The module of claim 9, wherein a network interlayer between the first network of first photovoltaic cells and the second network of second photovoltaic cells includes a graded refractive index.

15. The module of claim 9, wherein a network interlayer between the first network of first photovoltaic cells and the second network of second photovoltaic cells includes an insulator layer.

16. The module of claim 9, wherein a network interlayer between the first network of first photovoltaic cells and the second network of second photovoltaic cells includes a metallic material.

17. The module of claim 9, wherein a network interlayer between the first network of first photovoltaic cells and the second network of second photovoltaic cells includes an interlayer material manufactured under process conditions that are damaging to either the first or second photovoltaic cells.

18. The module of claim 9, wherein the first network comprises a hybrid integrated network of first photovoltaic cells and wherein the second network comprises a monolithically integrated network of second photovoltaic cells.

19. The module of claim 9, further comprising a network interconnect that electrically connects the second network of second photovoltaic cells to the first network of first photovoltaic cells, wherein the network interconnect is formed from a conductive material that is transmissive to a major portion of wavelengths in the first region of the first primary light absorption spectrum.

20. The module of any preceding claim, wherein the first primary light absorption spectrum includes at least a portion of the second primary light absorption spectrum.

21. A network interlayer for positioning between first and second networks of respective first and second photovoltaic cells having respective different first and second photovoltaic materials with respective first and second regions of light conversion activity that are characterized at least in part by respective different first and second primary light absorption spectra for absorbing incident photons having respective first and second wavelengths in the respective first and second primary light absorption spectra and generating electron and hole charge carriers in the respective first and second photovoltaic materials, the network interlayer comprising:
interlayer material having optical properties that enhance transmission of a major portion of the wavelengths in at least one of the primary light absorption spectra, the interlayer material including a thickness greater than 400 nm, an average transmittance of greater than 60% over a wavelength range of 600-1200 nm, and optical components that selectively reflect wavelengths less than 550 nm such that average reflectance of wavelengths less than 550 nm is greater than 50%.

22. The network interlayer of claim 21, further comprising a thickness greater than a wavelength corresponding to the lowest of the lower ends of the respective first and second primary absorption spectra of the first and second photovoltaic materials.

23. The network interlayer of any one of claim 21 or 22, further comprising a thickness greater than 1000 nm.

24. The network interlayer of any one of claims 21 to 23, further comprising an optical structure.

25. The network interlayer of claim 24, wherein the optical structure includes at least one of a layer of light-scattering or light-emitting particles embedded in a matrix, an optical grating, a multiple layer optical coating, and photonic crystals.

26. The network interlayer of any one of claims 21 to 24, further comprising a graded refractive index.

27. The network interlayer of any one of claims 21 to 26, further comprising an insulator layer.

28. The network interlayer of any one of claims 21 to 26, further comprising a metallic material.

29. The network interlayer of any one of claims 21 to 28, further comprising an interlayer material manufactured under process conditions that are damaging to either the first or second photovoltaic cells.

30. The network interlayer of any one of claims 21 to 29, further comprising an average of greater than 70% over a wavelength range of 600-1200 nm.

31. A multijunction solar panel, comprising:
a first network of first photovoltaic cells including a first photovoltaic material having a first region of light conversion activity that is characterized at least in part by a first primary light absorption spectrum for absorbing incident photons having a first wavelength in the first primary light absorption spectrum and generating electron and hole charge carriers in the first photovoltaic material, the first photovoltaic cells having a first surface area;
a first spaced-apart opposing pair of first electrically conductive layers positioned on opposing sides of the first photovoltaic material to collect electron and hole charge carriers separated by a first charge-separating junction in the first photovoltaic material, one of the first electrically conductive layers being transmissive to incident photons of a majority of wavelengths within the first primary light absorption spectrum to permit a majority of incident photons in the first primary light absorption spectrum to reach the first photovoltaic material;
a second network of second photovoltaic cells including a second photovoltaic material having a second region of light conversion activity that is characterized at least in part by a second primary light absorption spectrum for absorbing incident photons having a second wavelength in the second primary light absorption spectrum and generating electron and hole charge carriers in the second photovoltaic material, the second photovoltaic material being different from the first photovoltaic material, the second primary light absorption spectrum being different from the first primary light absorption spectrum such that the first primary light absorption spectrum includes a first subset of first wavelengths absent from the second primary light absorption spectrum, the second photovoltaic material being transmissive to a majority incident photons of a majority of wavelengths within the first subset of first wavelengths of the first primary light absorption spectrum, the second photovoltaic cells having a second surface area parallel to the first surface area and being positioned to spatially overlap at least a first portion of the first surface area, and the second surface area being different from the first surface area; and
a second spaced-apart opposing pair of second electrically conductive layers positioned on opposing sides of the second photovoltaic material to collect electron and hole charge carriers separated by a second charge-separating junction in the second photovoltaic material, at least one of the second electrically conductive layers being transmissive to incident photons of a majority or wavelengths within the first and second primary light absorption spectra to permit incident photons in the first and second primary light absorption spectra to reach the first and second photovoltaic materials, another of the second electrically conductive layers being transmissive to incident photons of a majority of the first subset of first wavelengths within the first primary light absorption spectrum to permit incident photons in the first subset of first wavelengths within the first primary light absorption spectrum to reach the first photovoltaic material.

32. The solar panel of claim 31 further comprising the interlayer of any one of claims 21 to 30.

33. The solar panel of claim 31 further comprising the subject matter of any one of claims 1-20.

34. A multijunction solar panel, comprising:
a first network of first photovoltaic cells including a first photovoltaic material having a first region of light conversion activity that is characterized at least in part by a first primary light absorption spectrum for absorbing incident photons having a first wavelength in the first primary light absorption spectrum and generating electron and hole charge carriers in the first photovoltaic material, the first network including a first number of first photovoltaic cells;
a first spaced-apart opposing pair of first electrically conductive layers positioned on opposing sides of the first photovoltaic material to collect electron and hole charge carriers separated by a first charge-separating junction in the first photovoltaic material, one of the first electrically conductive layers being transmissive to incident photons of a majority of wavelengths within the first primary light absorption spectrum to permit a majority of incident photons in the first primary light absorption spectrum to reach the first photovoltaic material;
a second network of second photovoltaic cells including a second photovoltaic material having a second region of light conversion activity that is characterized at least in part by a second primary light absorption spectrum for absorbing incident photons having a second wavelength in the second primary light absorption spectrum and generating electron and hole charge carriers in the second photovoltaic material, the second photovoltaic material being different from the first photovoltaic material, the second primary light absorption spectrum being different from the first primary light absorption spectrum such that the first primary light absorption spectrum includes a first subset of first wavelengths absent from the second primary light absorption spectrum, the second photovoltaic material being transmissive to a majority incident photons of a majority of wavelengths within the first subset of first wavelengths of the first primary light absorption spectrum, the second network including a second number of second photovoltaic cells in which the second number is different from the first number, the second network being positioned to spatially overlap at least a first portion of the first network; and
a second spaced-apart opposing pair of second electrically conductive layers positioned on opposing sides of the second photovoltaic material to collect electron and hole charge carriers separated by a second charge-separating junction in the second photovoltaic material, at least one of the second electrically conductive layers being transmissive to incident photons of a majority or wavelengths within the first and second primary light absorption spectra to permit incident photons in the first and second primary light absorption spectra to reach the first and second photovoltaic materials, another of the second electrically conductive layers being transmissive to incident photons of a majority of the first subset of first wavelengths within the first primary light absorption spectrum to permit incident photons in the first subset of first wavelengths within the first primary light absorption spectrum to reach the first photovoltaic material.

35. The solar panel of claim 34 further comprising the interlayer of any one of claims 21 to 30.

36. The solar panel of claim 34 further comprising the subject matter of any one of claims 1-20.

37. A photovoltaic cell adapted for use as an underlying photovoltaic cell in a module employing underlying and overlying photovoltaic cells, the photovoltaic cell comprising:
a photovoltaic material having a region of light conversion activity that is characterized at least in part by a primary light absorption spectrum for absorbing incident photons having wavelengths in a primary light absorption spectrum;
a top surface of the photovoltaic material;
a charge-separating junction;
an emitter layer within the photovoltaic material between the top surface and the charge separating junction; and
a characteristic for use for an underlying photovoltaic cell in a module employing underlying and overlying photovoltaic cells, the characteristic including one or more of the following optional characteristics: an emitter layer thickness that is greater than 100 nm; a junction depth that is greater than 100 nm; an emitter layer sheet resistance that is less than 45 Ohms/square; a top contact positioned above the top surface, the top contact including a gridline spacing that is greater than 3 mm; a top contact positioned above the top surface, the top contact including a gridline pattern that shades less than 8% of the top surface of the photovoltaic material; a top surface root mean square roughness that is less than 2000 nm; and an anti-reflection coating positioned above the top surface and/or below the photovoltaic material, the anti-reflection coating optionally including an SiOₓ layer having a thickness greater than 40 nm, an SiNₓ layer having a thickness greater than 25 nm, or both such SiOₓ and SiNₓ layers wherein the SiNₓ layer is positioned above the SiNₓ layer, and/or the anti-reflection coating optionally exhibiting a minimum reflectance wavelength between 700 and 1200 nm.

38. The photovoltaic cell of claim 37 in which the emitter layer thickness is greater than 200 nm or optionally greater than 250 nm.

39. The photovoltaic cell of any one of claims 37 to 38 in which the emitter layer thickness is between 250 and 800 nm, or optionally between 300 and 750 nm, or optionally between 500 and 700 nm.

40. The photovoltaic cell of any one of claims 37 to 39 in which the junction depth is greater than 200 nm or optionally greater than 250 nm.

41. The photovoltaic cell of any one of claims 37 to 40 in which the junction depth is between 250 and 800 nm, or optionally between 300 and 750 nm, or optionally between 500 and 700 nm.

42. The photovoltaic cell of any one of claims 37 to 41 in which the emitter layer sheet resistance is less than 30 Ohms/square, or optionally less than 25 ohms/square, or optionally less than 15 Ohms/square.

43. The photovoltaic cell of any one of claims 37 to 42 in which the emitter layer sheet resistance is between 10 and 40 Ohms/square, or optionally between 15 and 30 ohms/square.

44. The photovoltaic cell of any one of claims 37 to 43 in which the gridline spacing is greater than 4 mm, or optionally greater than 5 mm.

45. The photovoltaic cell of any one of claims 37 to 44 in which the gridline spacing is between 3 and 8 mm, or optionally between 3 and 6 mm.

46. The photovoltaic cell of any one of claims 37 to 45 in which the gridline pattern that shades less than 5% of the top surface of the photovoltaic material, or optionally shades less than 4% of the top surface of the photovoltaic material, or optionally shades less than 3% of the top surface of the photovoltaic material, or optionally shades less than 1% of the top surface of the photovoltaic material.

47. The photovoltaic cell of any one of claims 37 to 46 in which the anti-reflection coating includes an SiOₓ layer having a thickness greater than 50 nm, or optionally greater than 60 nm.

48. The photovoltaic cell of any one of claims 37 to 47 in which the anti-reflection coating includes an SiNₓ layer having a thickness greater than 40 nm, or optionally greater than 50 nm.

49. The photovoltaic cell of any one of claims 37 to 48 in which the anti-reflection coating exhibits a minimum reflectance wavelength that is greater than 700 nm, or optionally greater than 775 nm.

50. The photovoltaic cell of any one of claims 37 to 49 in which the anti-reflection coating exhibits a minimum reflectance wavelength between 750 and 1100 nm, or optionally between 800 and 1000 nm.

51. The photovoltaic cell of any one of claims 37 to 50 in which the characteristic is sub-optimized for performance of the photovoltaic cell as a stand-alone solar cell.

52. The photovoltaic cell of any one of claims 37 to 51 in which the emitter thickness causes the photovoltaic material to absorb fewer photons in a subset of the primary absorption spectra and generate less current than the same photovoltaic material having a thinner emitter.

53. The photovoltaic cell of any one of claims 37 to 52 optionally further comprising the subject matter of any one of claims 1-36.

54. A photovoltaic cell adapted for use as an overlying photovoltaic cell in a module employing underlying and overlying photovoltaic cells, the photovoltaic cell comprising:
a photovoltaic material having a region of light conversion activity that is characterized at least in part by a primary light absorption spectrum for absorbing incident photons having wavelengths in a primary light absorption spectrum;
a top surface of the photovoltaic material;
a charge-separating junction;
an emitter layer within the photovoltaic material between the top surface and the charge-separating junction; and
a characteristic for use for an overlying photovoltaic cell in a module employing underlying and overlying photovoltaic cells, the characteristic including one or more of the following optional characteristics:
1) wherein the charge-separating junction includes an i-layer and wherein the photovoltaic cell provides a stabilized open-circuit voltage between about 0.91 and about 1.3 V;
2) wherein the charge-separating junction includes an i-layer having a bandgap above 1.75 eV and including a-Si material derived from plasma enhanced chemical vapor deposition wherein the process gas includes a H₂/SiH₄ ratio above 10;
3) wherein the charge-separating junction includes an i-layer having a bandgap above 1.75 eV and including a-SiC derived from plasma enhanced chemical vapor deposition wherein the process gas includes monomethyl silane, hydrogen, and silane;
4) wherein the charge-separating junction includes an i-layer having a bandgap above 1.75 eV and including a-SiC derived from plasma enhanced chemical vapor deposition wherein the process gas includes methane, hydrogen, and silane;
5) wherein the charge-separating junction includes an i-layer that has a depth or thickness that is less than 175 nm;
6) wherein the charge-separating junction includes an i-layer having a bandgap above 1.78 eV;
7) wherein the underlying photovoltaic cell has a greater efficiency than that of the overlying photovoltaic cell in response to sunlight incident on the overlying photovoltaic cell;
8) wherein the fill factor is greater than 77%; and
9) wherein greater than 85% of the light incident on the overlying photovoltaic cell in the wavelength range of 300-900 nm reaches the underlying photovoltaic cell, and/or greater than 65% of the light incident on the overlying photovoltaic cell in the wavelength range of 900-1200 nm reaches the underlying photovoltaic cell, and/or greater than greater than 65% of the light incident on the overlying photovoltaic cell in the wavelength range of 700-1200 nm, and/or a transparent conductive oxide layer between the overlying and underlying photovoltaic cells has a sheet resistivity of less than 200 Ohms/square.

55. The photovoltaic cell of claim 54 in which the open-circuit voltage is optionally between 0.95 and 1.3 V, optionally between 0.91 and 1.1 V, optionally between 0.95 and 1.1 V, or optionally between 0.97 and 1.1 V.

56. The photovoltaic cell of claim 54 or claim 55 in which the overlying photovoltaic cell has a bandgap above 1.74 eV or optionally above 1.78 eV.

57. The photovoltaic cell of any one of claims 54 to 56 in which the overlying photovoltaic cell has a bandgap below 3.27 eV.

58. The photovoltaic cell of any one of claims 54 to 57 in which the overlying photovoltaic cell has a peak bandgap above 1.75 eV, optionally above 1.9 eV, optionally above 2.0 eV, or optionally above 2.1 eV.

59. The photovoltaic cell of any one of claims 54 to 58 in which the overlying photovoltaic cell has a peak bandgap below 3.0 eV.

60. The photovoltaic cell of any one of claims 54 to 59 in which the overlying photovoltaic cell has a peak absorption wavelength optionally below 710 nm or optionally below 660 nm.

61. The photovoltaic cell of any one of claims 54 to 60 in which the photovoltaic material includes a-Si derived from plasma enhanced chemical vapor deposition (PECVD) with a H₂/SiH₄ ratio optionally above 12 in the process gas or optionally above 15 in the process gas.

62. The photovoltaic cell of any one of claims 54 to 61 in which the photovoltaic material includes a-Si derived from plasma enhanced chemical vapor deposition (PECVD) with a H₂/SiH₄ ratio optionally between 10 and 20 in the process gas or optionally between 12 and 18 in the process gas.

63. The photovoltaic cell of any one of claims 54 to 62 in which the charge-separating junction includes an i-layer has a depth or thickness that is optionally less than 160 nm, optionally less than 150 nm, or optionally less than 140 nm.

64. The photovoltaic cell of any one of claims 54 to 63 in which the charge-separating junction includes an i-layer has a depth or thickness that is optionally between 110 and 175 nm, optionally between 120 and 160 nm, or optionally between 130 and 150 nm.

65. The photovoltaic cell of any one of claims 54 to 64 in which the underlying photovoltaic cell has an active-layer bandgap optionally below 1.7 eV, optionally below 1.6 eV, or optionally below 1.5 eV.

66. The photovoltaic cell of any one of claims 54 to 65 in which the underlying photovoltaic cell has an active-layer bandgap optionally between 1.0 and 1.5 eV.

67. The photovoltaic cell of any one of claims 54 to 66 in which the underlying photovoltaic cells have a peak bandgap optionally below 1.7 eV, optionally below 1.6 eV, or optionally below 1.5 eV.

68. The photovoltaic cell of any one of claims 54 to 67 in which the underlying photovoltaic cell has a peak bandgap optionally between 1.0 and 1.5 eV.

69. The photovoltaic cell of any one of claims 54 to 68 in which the underlying photovoltaic cell optionally includes mc-Si photovoltaic material, optionally includes adapted mc-Si photovoltaic material, optionally includes c-Si photovoltaic material, optionally includes CIGS photovoltaic material, or optionally includes CdTe photovoltaic material.

70. The photovoltaic cell of any one of claims 54 to 69 in which the overlying photovoltaic cell provides a short circuit current of less than 10 mA/cm².

71. The photovoltaic cell of any one of claims 54 to 70 in which the overlying photovoltaic cell provides a short circuit current of optionally less than 9 mA/cm², optionally less than 8 mA/cm², or optionally less than 7 mA/cm².

72. The photovoltaic cell of any one of claims 54 to 71 in which the overlying photovoltaic cell provides an efficiency of optionally less than or equal to 8%, optionally less than or equal to 7%, or optionally less than or equal to 6%.

73. The photovoltaic cell of any one of claims 54 to 72 in which the underlying photovoltaic cell provides an efficiency of more than 10% greater than the efficiency of the overlying photovoltaic cell.

74. The photovoltaic cell of any one of claims 54 to 73 in which the underlying photovoltaic cell provides an efficiency of optionally more than 20% greater or optionally more than 30% greater than the efficiency of the overlying photovoltaic cell.

75. The photovoltaic cell of any one of claims 54 to 74 in which the module employing the underlying photovoltaic cell and the overlying photovoltaic cell provides an efficiency of greater than 9%.

76. The photovoltaic cell of any one of claims 54 to 75 in which the module employing the underlying photovoltaic cell and the overlying photovoltaic cell provides an efficiency of optionally greater than 10% or optionally greater than 12%.

77. The photovoltaic cell of any one of claims 54 to 76 in which the module employing the underlying photovoltaic cell and the overlying photovoltaic cell is capable of generating a total power and in which the underlying photovoltaic cell is capable of generating more than 60% of the total power or optionally more than 65% of the total power.

78. The photovoltaic cell of any one of claims 54 to 77, further comprising a thin conductive oxide layer having a charge carrier mobility of 10 to 100 cm²/Vs and a carrier density of greater than 10¹⁹ cm⁻³.

79. The photovoltaic cell of any one of claims 54 to 78, further comprising a thin conductive oxide layer having thickness of less than 2 μm, of less than 1 μm, of less than 500 nm, of less than less than 200 nm, or of about 100 nm plus or minus 50 nm.

80. The photovoltaic cell of any one of claims 54 to 79 optionally further comprising the subject matter of any one of claims 1-53.

81. A method optionally employing the subject matter of any one of claims 1-80 for generating current from incident photons.

82. A multijunction photovoltaic device, comprising:
a first photovoltaic material having a first primary bandgap energy and a first charge separating junction;
a second photovoltaic material having a second primary bandgap energy and a second charge separating junction, wherein the first and second primary bandgap energies differ by less than 20%.
a tunnel junction positioned between the first and second photovoltaic materials; and
a third photovoltaic material that is different from the first and second photovoltaic materials, the third photovoltaic material having a third primary bandgap energy that differs from the first and second primary bandgap energies by more than 20%.

83. The multijunction photovoltaic device of claim 82, in which the first and second photovoltaic materials comprise a common material.

84. The multijunction photovoltaic device of claim 82, in which the first and second photovoltaic materials comprise amorphous silicon.

85. The multijunction photovoltaic device of claim 82, in which the first and second photovoltaic materials comprise one or more of: CdSe, InxGa1-xP, InxGa1-xN, amorphous Si:Ge, CuInxGa1-xSe2S2-y, amorphous SiC, CuInGaSe2, and CdTe.

86. The multijunction photovoltaic device of any one of claims 82-85, which the first and second photovoltaic materials have a compositional difference of less than 2% atomic.

87. The multijunction photovoltaic device of any one of claims 82-86, in which the first photovoltaic material has a first thickness, the second photovoltaic material has a second thickness, and the second thickness is greater than or equal to the first thickness.

88. The multijunction photovoltaic device of any one of claims 82-87, in which the first photovoltaic material has a first thickness in a range of 30-150 nm and the second photovoltaic material has a second thickness in a range of 100-350 nm.

89. The multijunction photovoltaic device of any one of claims 82-88, in which the first photovoltaic material has a first thickness of less than 100 nm and the second photovoltaic material has a second thickness less than 200 nm.

90. The multijunction photovoltaic device of any one of claims 82-89, in which the first and second primary bandgap energies differ by less than 5%.

91. The multijunction photovoltaic device of any one of claims 82-90, in which the first and second primary bandgap energies differ by less than 1%.

92. The multijunction photovoltaic device of any one of claims 82-91, in which the first photovoltaic material has a first primary bandgap energy within a range of 1.6-2.0 eV.

93. The multijunction photovoltaic device of any one of claims 82-92, in which the first photovoltaic material has a first primary bandgap energy within a range of 1.7-1.9 eV.

94. The multijunction photovoltaic device of any one of claims 82-93, further comprising:
a third photovoltaic material that is different from the first and second photovoltaic materials, the third photovoltaic material having a third primary bandgap energy within a range of 0.8-1.3 eV.

95. The multijunction photovoltaic device of any one of claims 82-94, further comprising:
a third photovoltaic material that is different from the first and second photovoltaic materials, the third photovoltaic material including crystalline silicon or multicrystalline silicon.

96. The multijunction photovoltaic device of any one of claims 82-95, further comprising:
a first electrode associated with the first photovoltaic material; and
a second electrode associated with the second photovoltaic material, wherein the first and second electrodes each include a transparent conductive oxide, and at least one of the first and second electrodes has a thickness that is less than or equal to 1 μm.

97. The multijunction photovoltaic device of any one of claims 82-96, further comprising:
a first electrode associated with the first photovoltaic material; and
a second electrode associated with the second photovoltaic material, wherein the first and second electrodes each include a transparent conductive oxide, and at least one of the first and second electrodes has a thickness that is less than or equal to 500 nm.

98. The multijunction photovoltaic device of any one of claims 82-97, further comprising:
a first electrode associated with the first photovoltaic material; and
a second electrode associated with the second photovoltaic material, wherein the first and second electrodes each include a transparent conductive oxide, and the first and second electrodes each have a thickness that is less than or equal to 500 nm.

99. The multijunction photovoltaic device of any one of claims 82-98, further comprising:
a first electrode associated with the first photovoltaic material; and
a second electrode associated with the second photovoltaic material, wherein the first and second electrodes each include a transparent conductive oxide, and at least one of the first and second electrodes has a thickness that is less than or equal to 200 nm.

100. The multijunction photovoltaic device of any one of claims 82-99, further comprising:
a first electrode associated with the first photovoltaic material; and
a second electrode associated with the second photovoltaic material, wherein the first and second electrodes each include a transparent conductive oxide, and at least one of the first and second electrodes has a thickness that is less than or equal to 100 nm.

101. The multijunction photovoltaic device of any one of claims 82-100, further comprising:
a first electrode associated with the first photovoltaic material; and
a second electrode associated with the second photovoltaic material, wherein the first and second electrodes each include a transparent conductive oxide layer that transmits at least 65% of incident light in the wavelength range of 700-1200 nm.

102. The multijunction photovoltaic device of any one of claims 82-101, in which the first and second photovoltaic materials are monolithically stacked.

103. The multijunction photovoltaic device of any one of claims 82-102, in which electrodes associated the first and second photovoltaic materials are connected electrically in series.

104. The multijunction photovoltaic device of any one of claims 82-103, in which the first photovoltaic material generates a first instantaneous current and the second photovoltaic material generates a second instantaneous current, and the first and second instantaneous currents differ by less than 5%.

105. The multijunction photovoltaic device of any one of claims 82-104, further comprising:
third and fourth electrodes associated with a third photovoltaic material positioned between them; and
an intercell layer positioned between the second and third photovoltaic materials.

106. The multijunction photovoltaic device of any one of claims 82-105, in which the first and second primary bandgap energies differ by less than 170 meV.

107. The multijunction photovoltaic device of any one of claims 82-106, in which the first photovoltaic material, the tunnel junction, and the second photovoltaic material are formed in a single chamber under continuous vacuum.

108. A multijunction photovoltaic device, comprising:
a first photovoltaic material including amorphous silicon having a first primary bandgap energy, a first charge separating junction, and a first thickness;
a second photovoltaic material, positioned beneath the first photovoltaic material, including amorphous silicon having a second primary bandgap energy, a second charge separating junction, and a second thickness greater than or equal to the first thickness; and
a third photovoltaic material, positioned beneath the second photovoltaic material, including crystalline silicon or multicrystalline silicon having a third primary bandgap energy and a third charge separating junction, the third bandgap energy being different from the first and second bandgap energies.

109. Any of the dependent claims 83, 84, and 86-107 directly or indirectly dependent on claim 108 instead of claim 82.

110. A multijunction photovoltaic device, comprising:
a first photovoltaic material having a first primary absorption spectrum for absorbing photons, the first photovoltaic material having a first thickness that limits a first amount of first instantaneous current generated in the first photovoltaic material from absorbed photons;
a second photovoltaic material having a second primary absorption spectrum for absorbing photons, the second photovoltaic material having a second thickness that limits a second amount of second instantaneous current generated in the second photovoltaic material from absorbed photons, the first and second photovoltaic materials having a compositional difference of less than 5% atomic, and the absorption of some photons in the first photovoltaic material preventing absorption of those photons in the second photovoltaic material, thereby also limiting the second amount of second instantaneous current generated in the second photovoltaic material from absorbed photons;
a third photovoltaic material that is different from the first and second photovoltaic materials, the third photovoltaic material having a third primary light absorption spectrum that is different from the first and second primary light absorption spectra;
a first transparent conductive oxide electrode associated with first photovoltaic material, the first transparent conductive oxide electrode having a first thickness and a first doping concentration that determine a first instantaneous current capacity of the first transparent conductive oxide electrode, the first thickness or first instantaneous current capacity having an inverse relationship with a first transmissivity of the first photovoltaic material to at least a first portion of the third primary light absorption spectrum; and
a second transparent conductive oxide electrode associated with second photovoltaic material, the second transparent conductive oxide electrode having a second thickness and a second doping concentration that determine a second instantaneous current capacity of the second transparent conductive oxide electrode, the second thickness or second instantaneous current capacity having an inverse relationship with a second transmissivity of the second photovoltaic material to at least a second portion of the third primary light absorption spectrum, wherein the first and second portions of the third primary light absorption spectra overlap by greater than 85%, wherein the first and second transmissivity to the first and second portions of the third primary light absorption spectra is greater than 85%, wherein the first instantaneous current is within 15% of the first instantaneous current capacity, and wherein the second instantaneous current is within 15% of the second instantaneous current capacity.

111. Any of the dependent claims 83-107 directly or indirectly dependent on claim 110 instead of claim 82.

112. A multijunction photovoltaic device, comprising:
a first photovoltaic material having a first primary bandgap energy and a first charge separating junction;
a second photovoltaic material having a second primary bandgap energy and a second charge separating junction, wherein the first and second primary bandgap energies differ by less than 20%;
a tunnel junction positioned between the first and second photovoltaic materials;
a first electrode associated with first photovoltaic material; and
a second electrode associated with the second photovoltaic material, wherein the first and second electrodes each include a transparent conductive oxide, and at least one of the first and second electrodes has a thickness that is less than or equal to 500 nm.

113. Any of the dependent claims 83-107 directly or indirectly dependent on claim 112 instead of claim 82.

114. A multijunction photovoltaic device, comprising:
a first photovoltaic material having a first primary bandgap energy, a first charge separating junction, and a first thickness;
a second photovoltaic material having a second primary bandgap energy, a second charge separating junction, and a second thickness greater than or equal to the first thickness;
a tunnel junction positioned between the first and second photovoltaic materials;
a first electrode associated with first photovoltaic material; and
a second electrode associated with the second photovoltaic material, wherein the first and second electrodes each include a transparent conductive oxide, and at least one of the first and second electrodes has a thickness that is less than or equal to 500 nm.

34. Any of the dependent claims 83-107 directly or indirectly dependent on claim 114 instead of claim 82.
